(19) United States
(12) Patent Application Publication
(10) Pub. No.: US 2020/0012191 A1
(43) Pub. Date: Jan. 9, 2020

(54) PHOTOSENSITIVE RESIN COMPOSITION, CURED FILM, ELEMENT EQUIPPED WITH CURED FILM, ORGANIC EL DISPLAY DEVICE EQUIPPED WITH CURED FILM, CURED FILM PRODUCTION METHOD, AND ORGANIC EL DISPLAY DEVICE PRODUCTION METHOD

(71) Applicant: TORAY INDUSTRIES, INC., Tokyo (JP)

(72) Inventors: Satoshi KAMEMOTO, Otsu-shi (JP); Yugo TANIGAKI, Otsu-shi (JP); Kazuto MIYOSHI, Otsu-shi (JP)

(73) Assignee: TORAY INDUSTRIES, INC., Tokyo (JP)

(21) Appl. No.: 16/491,039

(22) PCT Filed: Mar. 16, 2018
(86) PCT No.: PCT/JP2018/010458

§ 371 Date: Sep. 4, 2019

(30) Foreign Application Priority Data
Mar. 28, 2017 (JP) 2017-062368

(51) Int. Cl. G03F 7/037; C08L 79/08; C08L 33/10; C08L 57/00; C08K 3/04; C08K 5/00; C08F 2/48; G03F 1/00; H01L 51/50; H05B 33/10

(52) U.S. Cl. CPC G03F 7/037; C08L 79/08; C08L 33/10; C08L 57/00; C08K 3/04; C08K 5/0025; C08F 2810/00; G03F 1/00; H01L 51/50; H05B 33/10; C08L 2203/16; C08L 2203/20; C08F 2/48

(57) ABSTRACT

The present invention provides a photosensitive resin composition which has a light-blocking property, and at the same time, a high sensitivity, and has excellent half-tone characteristics. The present invention provides a photosensitive resin composition including an (A) alkali-soluble resin, a (B) radically polymerizable compound, a (C) photo initiator, and a (D) colorant, where the (A) alkali-soluble resin contains a polyimide, a polyimide precursor, a polybenzoxazole precursor, and/or a copolymer thereof, and the (B) radically polymerizable compound contains a (B-1) bifunctional or higher (meth)acrylic compound that has a glass transition temperature of 150° C. or higher as a homopolymer, and a (B-2) tetrafunctional or higher (meth)acrylic compound other than the (B-1).

### TECHNICAL FIELD

The present invention relates to a photosensitive resin composition and a cured film using the composition, an element equipped with the cured film, an organic EL display device equipped with the cured film, a method for producing the cured film, and a method for producing the organic EL display device.

### BACKGROUND ART

In recent years, many products that use organic electroluminescence (hereinafter, “organic EL”) display devices have been developed in display devices including thin displays, such as smartphones, tablet PCs, and televisions.

The organic EL light-emitting element is operated by applying a voltage or applying a current between a first electrode and a second electrode opposed to each other. In this regard, since the electric field is likely to be concentrated at edge parts of the electrodes which are small in radius of curvature, undesirable phenomenon such as dielectric breakdown or leakage current generation tends to occur at the edge parts.

In general, in the organic EL display device, an insulation layer referred to as a pixel defining layer is formed in order to divide the pixels of the light-emitting element from each other. After the formation of the pixel defining layer, a light-emitting layer is formed in a region corresponding to the pixel area, in which the pixel defining layer is opened to expose the first electrode which serves as a base. The second electrode is deposited on the light-emitting layer, and in order to prevent disconnection of the transparent electrode or metal electrode formed, a less-tapered pattern shape is required for the pixel defining layer.

In addition, for forming the light-emitting layer, in vapor deposition with an evaporation mask in contact with the pixel defining layer, but the large area of contact between the pixel defining layer and the evaporation mask causes a decrease in panel yield due to particle generation. In addition, the pixel defining layer is damaged by matters adhering to the evaporation mask, and the ingress of moisture causes deterioration of the light-emitting element. Thus, examples of a method for reducing the area of contact with the pixel defining layer include a method of making, in the deposition of the pixel defining layer as separate two layers, the dimension width of the second layer smaller, but because of the complicated process, the method has the problem of causing an increase in process time or a decrease in panel yield. Examples of a method for solving these problems include a method of forming a pattern with the use of a half-tone photomask as a photomask (see, for example, Patent Document 1). This is a method in which the formation of a pixel defining layer with a step shape by deposition of a single layer reduces the area of contact with the evaporation mask without increasing the process time. The deposition of a single layer for the pixel defining layer with a step shape typically uses a positive photosensitive resin composition containing a naphthoquinone diazide compound (see, for example, Patent Document 2).

On the other hand, for the purpose of enhancing the contrast of the organic EL display device, attempts has been made to provide the pixel defining layer with a light-blocking property, and positive coloring photosensitive resin compositions containing a light-blocking colorant have been proposed (see, for example, Patent Document 3). In order to provide the light-blocking property required for enhancing the contrast, there is a need to use a significant amount of colorant in the composition, and the radiation for exposure is absorbed by the colorant, thus hardly developing the photoreaction required for pattern formation at the bottom of the film, and there has been thus a problem that the sensitivity is significantly decreased.

On the other hand, in the case of a negative photosensitive resin composition which is used for a black matrix of a liquid crystal display, and the like, because of the system in which a radical generated by exposure to radiation causes a chain reaction to insolubilize the exposed part, even with the composition in which a colorant is used, it is possible to form a pattern with a relatively high sensitivity as compared with the positive type. As the colorant-containing negative photosensitive resin composition, compositions that use an acrylic resin or a cardo resin have been proposed (see, for example, Patent Document 4). In recent years, colorant-containing negative photosensitive resin compositions for so-called black column spacer formation have been proposed for providing a column spacer of a liquid crystal display device with a light-blocking property, and processing with the use of a half-tone photomask has made it possible to form spacers that differ in height (see, for example, Patent Document 5).

These conventionally known colorant-containing negative photosensitive resin compositions, however, have problems such as the fact that even when a pattern with a step shape after development is formed with the use of a half-tone photomask, the shape undergoes a change at the time of heat treatment, thereby failing to obtain a cured film with a desired step shape.

Accordingly, there has been demand for a photosensitive resin composition which has a light-blocking property, and at the same time, a high sensitivity, and has excellent characteristics capable of forming a pattern with a step shape by a collective process with the use of a half-tone photomask (hereinafter, half-tone characteristics).

### PRIOR ART DOCUMENTS

### Patent Documents

Patent Document 1: Japanese Patent Laid-open Publication No. 2005-322564 (claims 1 to 9)

Patent Document 2: Japanese Patent Laid-open Publication No. 2007-294118 (claim 5)

Patent Document 3: Japanese Patent Laid-open Publication (Translation of PCT Application) No. 2013-533508 (claims 1 to 19)

Patent Document 4: International Publication No. 2008/032675 (claims 1 to 8)

Patent Document 5: Japanese Patent Laid-open Publication No. 2016-177190 (claims 1 to 9)

### SUMMARY OF THE INVENTION

### Problems to be Solved by the Invention

Thus, an object of the present invention is to provide a photosensitive resin composition which has a light-blocking property, and at the same time, a high sensitivity, and has excellent half-tone characteristics.

In addition, as another problem, it is difficult to form a pixel defining layer with a step shape from a conventionally known negative photosensitive resin composition, and, the contact between an evaporation mask and the pixel defining layer may decrease the reliability of the light-emitting element.

Thus, an object of the present invention is to provide an organic EL display device including a pixel defining layer with a step shape where there is a sufficient film thickness difference between a thick film part and a thin film part, with excellent reliability for a light-emitting element.

Furthermore, as another subject, a complicated step may be required for forming the pixel defining layer with the step shape with the use of a conventionally known negative photosensitive resin composition.

Thus, an object of the present invention is to provide a method for forming a cured film with a step shape by a collective process with the use of a half-tone photomask, and a method for producing an organic EL display device with the use of the cured film.

### Solutions to the Problems

The photosensitive resin composition according to the present invention is a photosensitive resin composition including an (A) alkali-soluble resin, a (B) radically polymerizable compound, a (C) photo initiator, and a (D) colorant, where the (A) alkali-soluble resin contains a polyimide, a polyimide precursor, a polybenzoxazole precursor, and/or a copolymer thereof, and the (B) radically polymerizable compound contains a (B-1) bifunctional or higher (meth)acrylic compound that has a glass transition temperature of 150° C. or higher as a homopolymer, and a (B-2) tetrafunctional or higher (meth)acrylic compound other than the (B-1).

### Effects of the Invention

The photosensitive resin composition according to the present invention is capable of providing a photosensitive resin composition which has a light-blocking property, and at the same time, a high sensitivity, and has excellent half-tone characteristics. In addition, the use of the photosensitive resin composition makes it possible to form a cured film with a step shape where there is a sufficient film thickness difference between the thick film part and the thin film part, thus allowing the reliability for a light-emitting device to be improved. Furthermore, the use of the resin composition makes it possible to form a cured film with a step shape by a collective process with the use of a half-tone photomask, thus the process time to be shortened.

### BRIEF DESCRIPTION OF THE DRAWINGS

FIG. 1 is a sectional view illustrating a cross section example of a cured pattern with a step shape.

FIG. 2 is a sectional view of a TFT substrate with a planarization layer and a pixel defining layer formed.

FIG. 3 is a schematic view illustrating an example of a half-tone photomask.

FIG. 4 is a sectional view illustrating a cross section example of an insulation layer.

FIG. 5 is a SEM photograph showing a cross section example of a cured pattern with a step shape.

FIG. 6 is a SEM photograph showing a cross section example of a cured pattern with a step shape lost.

FIGS. 7(a) to 7(d) are schematic views of an organic EL display device used for the evaluation of light-emitting characteristics.

### EMBODIMENTS OF THE INVENTION

Embodiments of the present invention will be described in detail.

The photosensitive resin composition according to the present invention is a photosensitive resin composition including an (A) alkali-soluble resin, a (B) radically polymerizable compound, a (C) photo initiator, and a (D) colorant, where the (A) alkali-soluble resin contains a polyimide, a polyimide precursor, a polybenzoxazole precursor, and/or a copolymer thereof, and the (B) radically polymerizable compound contains a (B-1) bifunctional or higher (meth)acrylic compound that has a glass transition temperature of 150° C. or higher as a homopolymer, and a (B-2) tetrafunctional or higher (meth)acrylic compound other than the (B-1).

The photosensitive resin composition according to the present invention contains an (A) alkali-soluble resin. The alkali solubility in the present invention refers to allowing the dissolution rate determined from a reduction in film thickness in the case of applying a solution of the resin dissolved in γ-butyrolactone onto a silicon wafer, forming a prebaked film of 10 μm±0.5 μm in film thickness by pre-baking for 4 minutes at 120° C., immersing the prebaked film in a 2.38% by mass tetramethylammonium hydroxide aqueous solution at 23±1° C. for 1 minute, and then subjecting the film to a rinse treatment with pure water, to be 50 nm/minute or more.

Examples of the (A) alkali-soluble resin include a polyimide, a polyimide precursor, a polybenzoxazole, a polybenzoxazole precursor, a polyaminoamide, a polyamide, a polymer of a radically polymerizable monomer such as an acrylic resin, a siloxane resin, and a cardo resin, but the (A) alkali-soluble resin is not limited thereto. The photosensitive resin composition may contain two or more kinds of these resins. The photosensitive resin composition may be a copolymer of these resins.

Among these alkali-soluble resins, the resins are preferred which have excellent heat resistance and a small amount of outgassing under high temperature. Specifically, a polyimide, a polyimide precursor, a polybenzoxazole precursor, and/or copolymers thereof are preferred. More specifically, the (A) alkali-soluble resin according to the present invention contains a polyimide, a polyimide precursor, a polybenzoxazole precursor, and/or a copolymer thereof.

The polyimide, the polyimide precursor, and the polybenzoxazole precursor, and/or the copolymer thereof, which can be used as the (A) alkali-soluble resin according to the present invention, preferably have an acidic group in a structural unit of the resin and/or at a main-chain terminal thereof for the purpose of providing the photosensitive resin composition with the alkali solubility. Examples of the acidic group include a carboxyl group, a phenolic hydroxyl group, a sulfonic acid group, and a thiol group, for example.

Moreover, the alkali-soluble resin preferably has a fluorine atom, and at the time of development with an alkali aqueous solution, can provide the interface between a film and a base material with water repellency to suppress the alkali aqueous solution from permeating the interface. The fluorine atom content in the alkali-soluble resin is preferably 5% by mass or more from the viewpoint of the effect of preventing the alkali aqueous solution from permeating the interface, and is preferably 20% by mass or less in terms of solubility in the alkali aqueous solution.

The above-described polyimide preferably has a structural unit represented by the following general formula (1), and the above-described polyimide precursor and the polybenzoxazole precursor preferably have a structural unit represented by the following general formula (2). The above-described polyimide, polyimide precursor, and polybenzoxazole precursor may contain two or more of these structural units. A resin obtained by copolymerization of the structural unit represented by the general formula (1) and the structural unit represented by the general formula (2) may be used as the alkali-soluble resin.

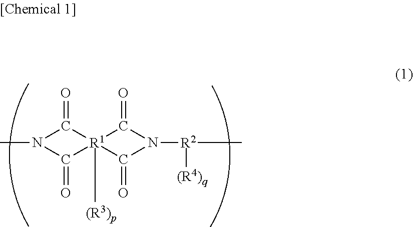

In the general formula (1), R¹ represents a tetravalent to decavalent organic group, and R² represents a divalent to octavalent organic group. R³ and R⁴ each represent a phenolic hydroxyl group, a carboxyl group, a sulfonic acid group, or a thiol group, and each thereof may have a single group, or different kinds of groups mixed. In the general formula (1), p and q each represent an integer of 0 to 6.

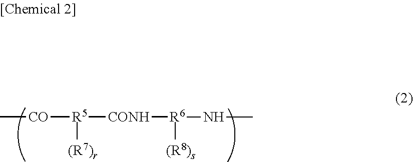

In the general formula (2), R⁵ represents a divalent to octavalent organic group, and R⁶ represents a divalent to octavalent organic group. R⁷ and R⁸ each represent a phenolic hydroxyl group, a sulfonic acid group, a thiol group, or COOR⁹, and each thereof may have a single group, or different kinds of groups mixed. R⁹ represents a hydrogen atom or a monovalent hydrocarbon group having 1 to 20 carbon atoms. In the general formula (2), r and s each represent an integer of 0 to 6, with the proviso that r+s>0.

The polyimide, the polyimide precursor, and the polybenzoxazole precursor, and/or the copolymer thereof preferably have 5 to 100000 structural units represented by the general formula (1) or the general formula (2). Furthermore, the polyimide, the polyimide precursor, and the polybenzoxazole precursor, and/or the copolymer thereof have other structural units in addition to the structural unit represented by the general formula (1) or (2). In this case, the polyimide, the polyimide precursor, and the polybenzoxazole precursor, and/or the copolymer preferably have the structural unit represented by the general formula (1) or the structural unit represented by the general formula (2) at 50% by mol or more of the total number of structural units.

In the foregoing general formula (1), R¹—(R³)ₚ represents a residue of an acid dianhydride. R¹ represents a tetravalent to decavalent organic group, and above all, an aromatic ring- or cycloaliphatic group-containing organic group having 5 to 40 carbon atoms is preferred.

Specifically, examples of the dianhydride include pyromellitic acid dianhydride, 3,3′,4,4′-biphenyltetracarboxylic acid dianhydride, 2,3,3′,4′-biphenyltetracarboxylic acid dianhydride, 2,2′,3,3′-biphenyltetracarboxylic acid dianhydride, 3,3′,4,4′-benzophenonetetracarboxylic acid dianhydride, 2,2′,3,3′-benzophenonetetracarboxylic acid dianhydride, 2,2-bis(3,4-dicarboxyphenyl)propane dianhydride, 2,2-bis(2,3-dicarboxyphenyl)propane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, bis(3,4-dicarboxyphenyl)ether dianhydride, 1,2,5,6-naphthalenetetracarboxylic acid dianhydride, 9,9-bis(3,4-dicarboxyphenyl)fluorene dianhydride, 9,9-bis{4-(3,4-dicarboxyphenoxy)phenyl}fluorene dianhydride, 2,3,6,7-naphthalenetetracarboxylic acid dianhydride, 2,3,5,6-pyridinetetracarboxylic acid dianhydride, 3,4,9,10-perylenetetracarboxylic acid dianhydride, 2,2-bis(3,4-dicarboxyphenyl)hexafluoropropane dianhydride, aromatic tetracarboxylic acid dianhydrides such as an acid dianhydride that has the structure shown below, and aliphatic tetracarboxylic acid dianhydrides such as butanetetracarboxylic acid dianhydride and 1,2,3,4-cyclopentanetetracarboxylic acid dianhydride. Two or more thereof may be used.

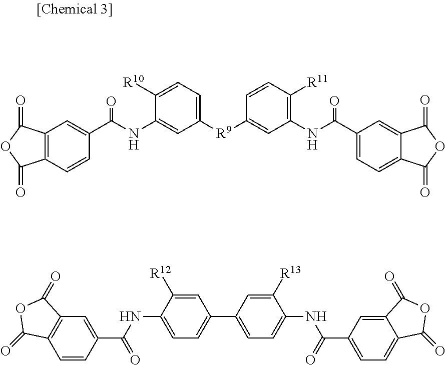

R⁹ represents an oxygen atom, C(CF₃)₂, or C(CH₃)₂. R¹⁰, R¹¹, R¹² and R¹³ each represent a hydrogen atom or a hydroxyl group.

In the foregoing general formula (2), R⁵—(R⁷)ᵣ represents a residue of an acid component. R⁵ represents a divalent to octavalent organic group, and above all, an aromatic ring- or cycloaliphatic group-containing organic group with 5 to 40 carbon atoms is preferred.

Examples of the acid component include, as examples of dicarboxylic acid, terephthalic acid, isophthalic acid, diphenyl ether dicarboxylic acid, bis(carboxyphenyl)hexafluoropropane, biphenyl dicarboxylic acid, benzophenone dicarboxylic acid, and triphenyl dicarboxylic acid. Examples of tricarboxylic acid include trimellitic acid, trimesic acid, diphenyl ether tricarboxylic acid, and biphenyl tricarboxylic acid. Examples of tetracarboxylic acid include pyromellitic acid, 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, 2,2′,3,3′-benzophenonetetracarboxylic acid, 2,2-bis(3,4-dicarboxyphenyl)hexafluoropropane, 2,2-bis(2,3-dicarboxyphenyl)hexafluoropropane, 1,1-bis(3,4-dicarboxyphenyl)ethane, 1,1-bis(2,3-dicarboxyphenyl)ethane, bis(3,4-dicarboxyphenyl)methane, bis(2,3-dicarboxyphenyl)methane, bis(3,4-dicarboxyphenyl)ether, 1,2,5,6-naphthalenetetracarboxylic acid, 2,3,6,7-naphthalenetetracarboxylic acid, 2,3,5,6-pyridinetetracarboxylic acid, 3,4,9,10-perylenetetracarboxylic acid, aromatic tetracarboxylic acids such as a tetracarboxylic acid that has the structure shown below, and aliphatic tetracarboxylic acids such as butanetetracarboxylic acid and 1,2,3,4-cyclopentanetetracarboxylic acid. Two or more thereof may be used.

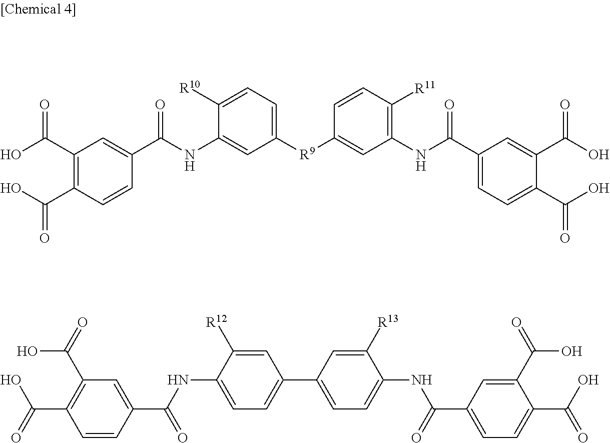

R⁹ represents an oxygen atom, C(CF₃)₂, or C(CH₃)₂. R¹⁰, R¹¹, R¹² and R¹³ each represent a hydrogen atom or a hydroxyl group.

Among these examples, in the tricarboxylic acids or the tetracarboxylic acids, one or two carboxyl group(s) corresponds (correspond) to the R⁷ group(s) in the general formula (2). Moreover, preferred are the dicarboxylic acids, tricarboxylic acids, or tetracarboxylic acids exemplified above with one to four hydrogen atom(s) substituted with R⁷ group(s) in the general formula (2), preferably phenolic hydroxyl group(s). These acids can be used directly, or as acid anhydrides or active esters.

R²—(R⁴)_{q} in the foregoing general formula (1) and R⁶—(R⁸)ₛ in the foregoing general formula (2) each represent a residue of a diamine. R² and R⁸ each represent a divalent to octavalent organic group, and above all, an aromatic ring- or cycloaliphatic group-containing organic group with 5 to 40 carbon atoms is preferred.

Specific examples of the diamine include 3,4′-diaminodiphenyl ether, 4,4′-diaminodiphenyl ether, 3,4′-diaminodiphenylmethane, 4,4′-diaminodiphenylmethane, 1,4-bis(4-aminophenoxy)benzene, benzidine, m-phenylenediamine, p-phenylenediamine, 1,5-naphthalenediamine, 2,6-naphthalenediamine, bis(4-aminophenoxy)biphenyl, bis{4-(4-aminophenoxy)phenyl}ether, 1,4-bis(4-aminophenoxy)benzene, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, 2,2′-di(trifluoromethyl)-4,4′-diaminobiphenyl, 9,9-bis(4-aminophenyl)fluorene, or a compound in which at least some of hydrogen atoms of the aromatic ring are substituted with alkyl groups or halogen atoms, an aliphatic cyclohexyldiamine, methylene biscyclohexylamine, and diamines that have the structure shown below. Two or more thereof may be used.

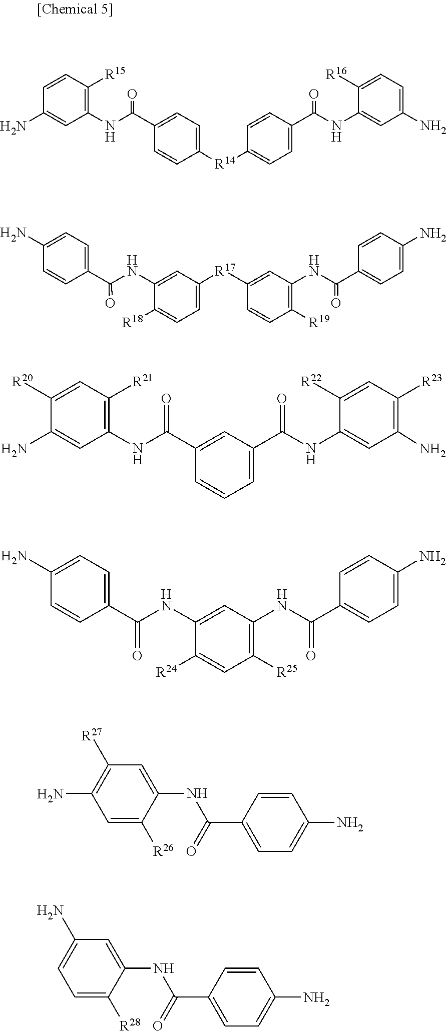

R¹⁴ and R¹⁷ each represent an oxygen atom, C(CF₃)₂ or C(CH₃)₂. R¹⁵, R¹⁶, and R¹⁸ to R²⁸ each independently represent a hydrogen atom or a hydroxyl group.

These diamines can be used as diamines, or as corresponding diisocyanate compounds or trimethylsilylated diamines.

Moreover, sealing the terminal of the resin with a monoamine having an acidic group, an acid anhydride, a monocarboxylic acid, a monoacid chloride, or a mono-active ester can provide a resin having an acidic group at a main-chain terminal.

Preferred examples of the monoamine having an acidic group include 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 3-amino-4,6-dihydroxypyrimidine, 2-aminophenol, 3-aminophenol, 4-aminophenol, 2-aminothiophenol, and 3-aminothiophenol, 4-aminothiophenol. Two or more thereof may be used.

Preferred examples of the acid anhydride, acid chloride, and monocarboxylic acid include acid anhydrides such as phthalic anhydride, maleic anhydride, nadic acid anhydride, cyclohexanedicarboxylic acid anhydride, and 3-hydroxyphthalic acid anhydride; a kind of monocarboxylic acids such as 3-carboxyphenol, 4-carboxyphenol, 3-carboxythiophenol, 4-carboxythiophenol, 1-hydroxy-7-carboxynaphthalene, 1-hydroxy-6-carboxynaphthalene, 1-hydroxy-5-carboxynaphthalene, 1-mercapto-7-carboxynaphthalene, 1-mercapto-6-carboxynaphthalene, and 1-mercapto-5-carboxynaphthalene, and a monoacid chloride in which the carboxyl group of the monocarboxylic acid is turned into an acid chloride; a monoacid chloride in which only one carboxyl group of dicarboxylic acids such as terephthalic acid, phthalic acid, maleic acid, cyclohexanedicarboxylic acid, 1,5-dicarboxynaphthalene, 1,6-dicarboxynaphthalene, 1,7-dicarboxynaphthalene, and 2,6-dicarboxynaphthalene is turned into an acid chloride; and a mono-active ester obtained by a reaction between a monoacid chloride and N-hydroxybenzotriazole or N-hydroxy-5-norbornene-2,3-dicarboximide. Two or more thereof may be used.

The content of an end-capping agent such as the monoamine, acid anhydride, monocarboxylic acid, monoacid chloride, and mono-active ester mentioned above is preferably 2 to 25% by mol with respect to 100% by mol of the sum of the acid and amine components constituting the resin.

The end-capping agent introduced into the resin can be easily detected by the following method. For example, the end-capping agent can be easily detected by dissolving, in an acidic solution, the resin with the end-capping agent introduced, then decomposing the resin into an amine component and an acid component as constitutional units of the resin, and subjecting the components to gas chromatography (GC) and NMR measurement. Alternatively, it is possible to detect end-capping agent by directly subjecting the resin with the end-capping agent introduced to pyrolysis gas chromatography (PGC), infrared spectrum measurement, and ¹³C-NMR spectrum measurement.

The (A) alkali-soluble resin for use in the present invention can be synthesized by a known method.

In the case of the polyimide precursor, the precursor can be synthesized by, as a production method thereof, for example, a method of allowing a tetracarboxylic acid dianhydride and a diamine compound to undergo a reaction at a low temperature, a method of obtaining a diester from a tetracarboxylic acid dianhydride and an alcohol, and then allowing the diester to undergo a reaction with an amine in the presence of a condensation agent, a method of obtaining a diester from a tetracarboxylic acid dianhydride and an alcohol, and then turning the residual dicarboxylic acid into an acid chloride, and allowing the acid chloride to undergo a reaction with an amine, or the like.

In the case of the polybenzoxazole precursor, the precursor can be obtained by, as a production method thereof, for example, allowing a bisaminophenol compound and a dicarboxylic acid to undergo a condensation reaction. Specifically, examples of the production method include a method of allowing a dehydration condensation agent such as dicyclohexylcarbodiimide (DCC) and an acid to undergo a reaction and adding a bisaminophenol compound thereto, and a method of adding a solution of a dicarboxylic acid dichloride dropwise into a solution of a bisaminophenol compound with a tertiary amine such as pyridine added thereto.

In the case of the polyimide, the polyimide can be obtained by, as a production method thereof, for example, dehydration and cyclization of the polyimide precursor obtained by the above-described method, through heating, or a chemical treatment with an acid, a base, or the like.

The photosensitive resin composition according to the present invention may contain an alkali-soluble resin other than polyimides, polyimide precursors, polybenzoxazole precursors, and/or copolymer thereof, as long as the heat resistance of the cured film is not impaired.

Examples of the alkali-soluble resins other than polyimides, polyimide precursors, polybenzoxazole precursors and/or copolymers thereof include polymers of radically polymerizable monomers such as acrylic resins, siloxane resins, and cardo resins. The use of one or more alkali-soluble resins selected from the foregoing resins in combination with one or more alkali-soluble resins selected from polyimides, polyimide precursors, polybenzoxazole precursors and/or copolymers thereof makes it possible to obtain a cured film which has a less tapered pattern shape. In the case of containing an alkali-soluble resin other than polyimides, polyimide precursors, polybenzoxazole precursors, and/or copolymers thereof, the content ratio thereof is preferably 5 parts by mass or more, and preferably 50 parts by mass or less with respect to 100 parts by mass of the whole of the (A) alkali-soluble resin. The ratio of 5 parts by mass or more can achieve a much less tapered effect, and the ratio of 50 parts by mass or less achieves sufficient heat resistance.

The photosensitive resin composition according to the present invention contains a (B) radically polymerizable compound. The (B) radically polymerizable compound has an unsaturated bond in the molecule. Examples of unsaturated bonds include unsaturated double bonds such as a vinyl group, an allyl group, an acryloyl group, and a methacryloyl group, and unsaturated triple bonds such as a propargyl group. Among these groups, the acryloyl group and the methacryloyl group are preferred in view of polymerizability. The (B) radically polymerizable compound is preferably a polyfunctional monomer having an acryloyl group or a methacryloyl group. Hereinafter, a compound having an acryloyl group or a methacryloyl group is referred to as a (meth)acrylic compound.

The photosensitive resin composition according to the present invention preferably has a glass transition temperature of 100° C. or higher, preferably 110° C. or higher, more preferably 120° C. or higher, particularly preferably 130° C. or higher, or most preferably 140° C. or higher, in a case where the (B) radically polymerizable compound is regarded as a polymer. The glass transition temperature of 100° C. or higher as a polymer makes, in a case where a pattern with a step shape is formed after development, it possible to suppress the change in shape and the flow of the pattern during the heat treatment, and obtain, after the heat treatment, a cured film with a desired step shape.

The photosensitive resin composition according to the present invention preferably has a glass transition temperature of 250° C. or lower, more preferably 230° C. or lower, further preferably 200° C. or lower, particularly preferably 180° C. or lower, or most preferably 160° C. or lower, in a case where the (B) radically polymerizable compound is regarded as a polymer. The glass transition temperature as a polymer is adjusted to 250° C. or lower, thereby allowing the pattern shape after curing by heating to be much less tapered.

It is to be noted that the glass transition temperature Tgp (K) in a case where the (B) radically polymerizable compound is regarded as a polymer is determined as in the following formula, from the weight fraction Wn of each monomer constituting the (B) radically polymerizable compound and the glass transition temperature Tgn (K) for each monomer as a homopolymer.

1/Tgp=Σ(Wn/Tgn)

In this regard, as the glass transition temperature Tgn (K) for each monomer as a homopolymer, the catalog value of a literature or a manufacturer is adopted, if any, or if not any, the value is adopted which is measured by differential scanning calorimetry (DSC) in accordance with JIS K 7121:2012 “Testing Methods for Heat of Transitions of Plastics”.

The photosensitive resin composition according to the present invention contains, as the (B) radically polymerizable compound, a (B-1) bifunctional or higher (meth)acrylic compound that has a glass transition temperature of 150° C. or higher as a homopolymer, and a (B-2) tetrafunctional or higher (meth)acrylic compound other than the (B-1).

Containing, as the (B) radically polymerizable compound, the (B-1) bifunctional or higher (meth)acrylic compound that has a glass transition temperature of 150° C. or higher as a homopolymer makes, in a case where a pattern with a step shape is formed after development, it possible to suppress the change in shape and the flow of the pattern during the heat treatment, and obtain, after the heat treatment, a cured film with a desired step shape. The glass transition temperature of the (B-1) component is 150° C. or higher, preferably 160° C. or higher, more preferably 170° C. or higher, further preferably 180° C. or higher, particularly preferably 190° C. or higher, in that it is possible to suppress the change in shape and the flow of the pattern during the heat treatment.

On the other hand, the glass transition temperature of the (B-1) component is preferably 300° C. or lower, more preferably 290° C. or lower, further preferably 280° C. or lower, particularly preferably 270° C. or lower. The glass transition temperature of the (B-1) component is adjusted to 300° C. or lower, thereby allowing the pattern shape after curing by heating to be much less tapered. The number of functional groups of the (B-1) component is adjusted to 2 or more, thereby making it possible to improve the sensitivity at the time of exposure, and the number is preferably 6 or less, more preferably 5 or less, further preferably 4 or less, particularly preferably 3 or less. The number of functional groups is adjusted to 6 or less, thereby allowing the pattern shape after curing by heating to be much less tapered.

Containing, as the (B) radically polymerizable compound, the (B-2) tetrafunctional or higher (meth)acrylic compound other than the (B-1) increases the density of photocrosslinking by exposure, thereby making it possible to achieve a higher sensitivity, and the use of the (B-2) in combination with the component (B-1) allows the pattern shape after curing by heating to be less tapered while maintaining the effect of suppressing the change in shape and the flow of the pattern during the heat treatment. The number of functional groups of the (B-2) tetrafunctional or higher (meth)acrylic compound other than the (B-1) is 4 or more, preferably 5 or more, and more preferably 6 or more. The number of functional groups is adjusted to 4 or more, thereby making it possible to achieve a higher sensitivity.

On the other hand, the number of functional groups of the (B-2) tetrafunctional or higher (meth)acrylic compound other than the (B-1) is preferably 12 or less, more preferably 10 or less, further preferably 8 or less. The number of functional groups is adjusted to 12 or less, thereby allowing the pattern shape after curing by heating to be much less tapered.

The (B-1) bifunctional or higher (meth)acrylic compound that has a glass transition temperature of 150° C. or higher as a homopolymer is preferably a compound that has an alicyclic structure in that the sensitivity at the time of exposure can be improved. Preferred examples of the alicyclic structure include a tricyclodecanyl group, a pentacyclopentadecanyl group, an adamantyl group, a hydroxyadamantyl group, and an isocyanurate group. Among the alicyclic structures, an alicyclic structure composed of only carbon atoms and hydrogen atoms is more preferred in that the structure is highly hydrophobic, capable of further improving the sensitivity at the time of exposure, and capable of reducing the water absorption of the cured film, and preferred examples of the alicyclic structure include a tricyclodecanyl group, a pentacyclopentadecanyl group, and an adamantyl group.

The (B-1) bifunctional or higher (meth)acrylic compound that has a glass transition temperature of 150° C. or higher as a homopolymer further preferably contains a methacrylic group, in that the group is highly hydrophobic, capable of further improving the sensitivity at the time of exposure, and capable of reducing the water absorption of the cured film.

Specific examples of the (B-1) bifunctional or higher (meth)acrylic compound that has a glass transition temperature of 150° C. or higher as a homopolymer include, but are not limited to, dimethylol tricyclodecane diacrylate, dimethylol tricyclodecane dimethacrylate, 1,3-adamantane diacrylate, 1,3-adamantane dimethacrylate, 1,3,5-adamantane triacrylate, 1,3,5-adamantane trimethacrylate, 5-hydroxy-1,3-adamantane diacrylate, 5-hydroxy-1,3-adamantane dimethacrylate, pentacyclopentadecane dimethanol diacrylate, pentacyclopentadecane dimethanol diacrylate, isocyanuric acid ethylene oxide modified diacrylate, isocyanuric acid ethylene oxide-modified dimethacrylate, isocyanuric acid ethylene oxide-modified triacrylate, or isocyanuric acid ethylene oxide modified trimethacrylate.

The (B-2) tetrafunctional or higher (meth)acrylic compound other than the (B-1) preferably contains a (meth)acrylic compound containing a structure represented by the general formula (3).

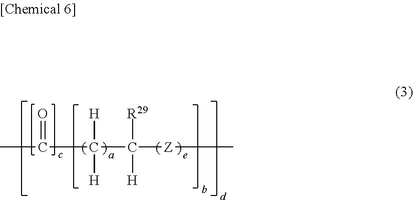

In the general formula (3), R²⁹ represents hydrogen or a hydrocarbon group having 1 to 10 carbon atoms. Z represents either an oxygen atom or N—R³⁰. R³⁰ represents a hydrogen atom or a hydrocarbon group having 1 to 10 carbon atoms. a represents an integer of 1 to 10, b represents an integer of 1 to 10, c represents 0 or 1, d represents an integer of 1 to 4, and e represents 0 or 1. In a case where c is 0, d is 1.

Containing the structure represented by the general formula (3) as the (B-2) tetrafunctional or higher (meth)acrylic compound other than the (B-1) causes UV curing at the time of exposure to proceed efficiently, thereby making it possible to improve the sensitivity at the time of exposure. In addition, in the case of containing a pigment as a (D) colorant to be described later, it is possible to suppress the generation of a residue derived from the pigment after development. The effect of increasing the sensitivity or suppressing the residue is presumed to be because the structure represented by the general formula (3) has an aliphatic chain and a flexible structure, thus increasing the probability of collision between ethylenically unsaturated double bond groups between molecules, then accelerating the UV curing, and improving the crosslink density.

The general formula (3) represents a (meth)acrylic compound having a lactone-modified chain, in a case where Z represents an oxygen atom, with b=1, c=1, and e=1, a (meth)acrylic compound having a lactam-modified chain, in a case where Z represents N—R³⁰, with b=1, c=1, and e=1, or a (meth)acrylic compound having an alkylene oxide-modified chain, in a case where Z represents an oxygen atom, with c=0, d=0, and e=1. Among these compounds, the (meth)acrylic compound having a lactone-modified chain and/or a lactam-modified chain is preferred in that the compound is capable of producing the effect of suppressing the change in shape and the flow of the pattern during the heat treatment, in addition to the above-mentioned increased sensitivity and reduced residue. Although the reason why the (meth)acrylic compound having a lactone-modified chain and/or a lactam-modified chain exhibits the effect of suppressing the change in shape and the flow of the pattern during the heat treatment is not clear, the action of a hydrogen bond between the carbonyl group and the oxygen or nitrogen atom in the general formula (3), in addition to the efficiently proceeding UV curing at the time of exposure, is assumed to contribute to the suppression of the flow.

Specific examples of the (B-2) tetrafunctional or higher (meth)acrylic compound other than the (B-1) include, but are not limited to, the following as (meth)acrylic compounds containing the structure represented by the general formula (3). Examples of the (meth)acrylate compound having a lactone-modified chain include ε-caprolactone-modified dipentaerythritol penta(meth)acrylate, ε-caprolactone-modified dipentaerythritol hexa(meth)acrylate, 6-valerolactone-modified dipentaerythritol penta(meth)acrylate, 6-valerolactone-modified dipentaerythritol hexa(meth)acrylate, γ-butyrolactone-modified dipentaerythritol penta(meth)acrylate, γ-butyrolactone-modified dipentaerythritol hexa(meth)acrylate, or “KAYARAD” (registered trademark) DPCA-20, DPCA-30, DPCA-60, or DPCA-120 (all manufactured by Nippon Kayaku Co., Ltd.).

Examples of the (meth)acrylate compound having a lactam-modified chain include ε-caprolactam-modified dipentaerythritol penta(meth)acrylate and ε-caprolactam-modified dipentaerythritol hexa(meth)acrylate, and examples of the (meth)acrylic compound having an alkylene oxide-modified chain include ethylene oxide-modified dipentaerythritol hexa(meth)acrylate, propylene oxide-modified dipentaerythritol hexa(meth)acrylate, butylene oxide-modified dipentaerythritol hexa(meth)acrylate, ethylene oxide-modified dipentaerythritol penta(meth)acrylate, propylene oxide-modified dipentaerythritol penta(meth)acrylate, butylene oxide-modified dipentaerythritol penta(meth)acrylate, ethylene oxide-modified pentaerythritol tetra(meth)acrylate, propylene oxide-modified pentaerythritol tetra(meth)acrylate, butylene oxide-modified pentaerythritol tetra(meth)acrylate, ethylene oxide-modified dimethylolpropane tetra(meth)acrylate, propylene oxide-modified dimethylolpropane tetra(meth)acrylate, and butylene oxide-modified dimethylolpropane tetra(meth)acrylate.

Specific examples of the (B-2) tetrafunctional or higher (meth)acrylic compound other than the (B-1), other than the (meth)acrylic compound containing the structure represented by the general formula (3) include, but are not limited to, pentaerythritol tetra(meth)acrylate, ditrimethylolpropane tetra(meth)acrylate, dipentaerythritol tetra(meth)acrylate, dipentaerythritol penta(meth)acrylate, ditrimethylolpropane penta(meth)acrylate, dipentaerythritol hexa(meth)acrylate, ditrimethylolpropane hexa(meth)acrylate, tripentaerythritol hepta(meth)acrylate, and tripentaerythritol octa(meth)acrylate.

As the (B) radically polymerizable compound, radically polymerizable compounds other than the above-described (B-1) and (B-2) may be contained, and examples thereof include styrene, α-methylstyrene, butyl (meth)acrylate, isobutyl (meth)acrylate, hexyl (meth)acrylate, isooctyl (meth)acrylate, isobornyl (meth)acrylate, cyclohexyl (meth)acrylate, N,N-dimethylaminoethyl (meth)acrylate, diethylene glycol di(meth)acrylate, triethylene glycol di(meth)acrylate, tetraethylene glycol di(meth)acrylate, propylene glycol di(meth)acrylate, trimethylolpropane di(meth)acrylate, trimethylolpropane tri(meth)acrylate, ethoxylated trimethylolpropane di(meth)acrylate, ethoxylated trimethylolpropane tri(meth)acrylate, ditrimethylolpropane tri(meth)acrylate, ditrimethylolpropane tetra(meth)acrylate, 1,3-butanediol di(meth)acrylate, neopentyl glycol di(meth)acrylate, 1,4-butanediol di(meth)acrylate, 1,6-hexanediol di(meth)acrylate, 1,9-nonanediol di(meth)acrylate, 1,10-decanediol di(meth)acrylate, dimethylol-tricyclodecane di(meth)acrylate, ethoxylated glycerin tri(meth)acrylate, pentaerythritol tri(meth)acrylate, ethylene oxide-modified bisphenol A di(meth)acrylate, propylene oxide-modified bisphenol A di(meth)acrylate, 1,3-butanediol diacrylate, 1,3-butanediol dimethacrylate, neopentyl glycol diacrylate, 1,4-butanediol diacrylate, 1,4-butanediol dimethacrylate, 1,6-hexanediol diacrylate, 1,6-hexanediol dimethacrylate, 1,9-nonanediol dimethacrylate, and 1,10-decanediol dimethacrylate.

The content of the (B) radically polymerizable compound is preferably 10 parts by mass or more, more preferably 20 parts by mass or more, further preferably 30 parts by mass or more, particularly preferably 50 parts by mass or more, with respect to 100 parts by mass of the (A) alkali-soluble resin. In addition, the content is preferably 300 parts by mass or less, more preferably 200 parts by mass or less, further preferably 150 parts by mass or less, particularly preferably 100 parts by mass or less. The content of 10 parts by mass or more makes it possible to reduce the thickness decrease of the exposed part during development, and the content of 300 parts by mass or less makes it possible to improve the heat resistance of the cured film.

Furthermore, the content of the (B-1) bifunctional or higher (meth)acrylic compound that has a glass transition temperature of 150° C. or higher as a homopolymer with respect to 100 parts by mass of the (B) radically polymerizable compound is preferably 20 parts by mass or more, more preferably 30 parts by mass or more, further preferably 40 parts by mass or more. In addition, the content is preferably 80 parts by mass or less, more preferably 70 parts by mass or less, further preferably 60 parts by mass or less. The content of 20 parts by mass or more makes, in a case where a pattern with a step shape is formed after development, it possible to further enhance the effect of suppressing the change in shape and the flow of the pattern during the heat treatment, and makes it easier to obtain, after the curing by heating, a cured film with a desired step shape. In addition, the content is adjusted to 80 parts by mass or less, thereby allowing the pattern shape after curing by heating to be much less tapered.

Furthermore, the content of the (B-2) tetrafunctional or higher (meth)acrylic compound other than the (B-1) with respect to 100 parts by mass of the (B) radically polymerizable compound is preferably 20 parts by mass or more, more preferably 30 parts by mass or more, further preferably 40 parts by mass or more. In addition, the content is preferably 80 parts by mass or less, more preferably 70 parts by mass or less, further preferably 60 parts by mass or less. The content is adjusted to 20 parts by mass or more, thereby increasing the density of photocrosslinking by exposure, and then allowing the sensitivity to be further increased, and the content is adjusted to 80 parts by mass or less, thereby making, in a case where a pattern with a step shape is formed after development, it possible to further enhance the effect of suppressing the change in shape and the flow of the pattern during the heat treatment.

The photosensitive resin composition according to the present invention contains a (C) photo initiator. Containing the photo initiator causes radical polymerization of the above-described (B) radically polymerizable compound to proceed, thereby making the exposed part of the film of the resin composition insoluble in an alkaline developer, and then allowing a negative pattern to be formed. In addition, UV curing during the exposure is accelerated, thereby allowing the sensitivity to be improved.

As the (C) photo initiator, for example, a benzyl ketal-based photo initiator, an α-hydroxy ketone-based photo initiator, an α-amino ketone-based photo initiator, an acylphosphine oxide-based photo initiator, an oxime ester-based photo initiator, an acridine-based photo initiator, a titanocene-based photo initiator, a benzophenone-based photo initiator, an acetophenone-based photo initiator, an aromatic ketoester-based photo initiator, or a benzoic acid ester-based photo initiator is preferred, and from the viewpoint of improvement in sensitivity at the time of exposure, an α-hydroxy ketone-based photo initiator, an α-amino ketone-based photo initiator, an acylphosphine oxide-based photo initiator, an oxime ester-based photo initiator, an acridine-based photo initiator, or a benzophenone-based photo initiator is more preferred, and an α-amino ketone-based photo initiator, an acylphosphine-based photo initiator, or an oxime ester-based photo initiator is further preferred.

Examples of the benzyl ketal-based photo initiator include 2,2-dimethoxy-1,2-diphenylethane-1-one.

Examples of the α-hydroxy ketone-based photo initiators include 1-(4-isopropylphenyl)-2-hydroxy-2-methylpropan-1-one, 2-hydroxy-2-methyl-1-phenylpropane-1-one, 1-hydroxycyclohexyl phenyl ketone, 1-[4-(2-hydroxyethoxy)phenyl]-2-hydroxy-2-methylpropane-1-one, or 2-hydroxy-1-[4-[4-(2-hydroxy-2-methylpropionyl)benzyl]phenyl]-2-methylpropan-1-one.

Examples of the α-amino ketone-based photo initiator include 2-methyl-1-[4-(methylthio)phenyl]-2-morpholinopropan-1-one, 2-benzyl-2-dimethylamino-1-(4-morpholinophenyl)-butane-1-one, 2-dimethylamino-2-(4-methylbenzyl)-1-(4-morpholinophenyl)-butane-1-one, or 3,6-bis(2-methyl-2-morpholinopropionyl)-9-octyl-9H-carbazole.

Examples of the acyl phosphine oxide-based photo initiator include 2,4,6-trimethyl benzoyl-diphenyl phosphine oxide, bis(2,4,6-trimethyl benzoyl)-phenyl phosphine oxide, or bis(2,6-dimethoxy benzoyl)-(2,4,4-trimethylpentyl)phosphine oxide.

Examples of the oxime ester-based photo initiator include 1-phenylpropane-1,2-dione-2-(O-ethoxycarbonyl)oxime, 1-phenylbutane-1,2-dione-2-(O-methoxycarbonyl)oxime, 1,3-diphenylpropane-1,2,3-trione-2-(O-ethoxycarbonyl)oxime, 1-[4-(phenylthio)phenyl]octane-1,2-dione-2-(O-benzoyl)oxime, l-[4-[4-(carboxyphenyl)thio]phenyl]propane-1,2-dione-2-(0-acetyl)oxime, 1-[9-ethyl-6-(2-methylbenzoyl)-9H-carbazol-3-yl]ethanone-1-(O-acetyl)oxime, 1-[9-ethyl-6-[2-methyl-4-[1-(2,2-dimethyl-1,3-dioxolan-4-yl) methyloxy]benzoyl]-9H-carbazol-3-yl]ethanone-1-(O-acetyl)oxime, or 1-(9-ethyl-6-nitro-9H-carbazole-3-yl)-1-[2-methyl-4-(1-methoxypropan-2-yloxy)phenyl]methanone-1-(O-acetyl) oxime.

Examples of the acridine-based photo initiator include 1,7-bis(acridin-9-yl)-n-heptane.

Examples of the titanocene-based photo initiator include bis(η⁵-2,4-cyclopentadien-1-yl)-bis[2,6-difluoro)-3-(1H-pyrrol-1-yl)phenyl] titanium (IV) or bis(η⁵-3-methyl-2,4-cyclopentadien-1-yl)-bis(2,6-difluorophenyl) titanium (IV).

Examples of the benzophenone-based photo initiator include benzophenone, 4,4′-bis(dimethylamino)benzophenone, 4,4′-bis(diethylamino)benzophenone, 4-phenylbenzophenone, 4,4-dichlorobenzophenone, 4-hydroxybenzophenone, alkylated benzophenone, 3,3′,4,4′-tetrakis(t-butylperoxycarbonyl)benzophenone, 4-methylbenzophenone, dibenzyl ketone, or fluorenone.

Examples of the acetophenone-based photo initiator include 2,2-diethoxyacetophenone, 2,3-diethoxyacetophenone, 4-t-butyldichloroacetophenone, benzalacetophenone, or 4-azidobenzalacetophenone.

Examples of the aromatic ketoester-based photo initiator include methyl 2-phenyl-2-oxyacetate.

Examples of the benzoate-based photo initiator include ethyl 4-dimethylaminobenzoate, (2-ethyl)hexyl 4-dimethylaminobenzoate, ethyl 4-diethylaminobenzoate, or methyl 2-benzoylbenzoate.

The content of the (C) photo initiator is preferably 0.5 parts by mass or more, more preferably 1 part by mass or more, further preferably 2 parts by mass or more, and preferably 50 parts by mass or less, more preferably 30 parts by mass or less, further preferably 20 parts by mass or less, with respect to 100 parts by mass of the (A) alkali-soluble resin. The content of the (C) photo initiator is adjusted to 0.5 parts by mass or more, thereby making it possible to reduce the thickness decrease of the exposed part during development, and the content thereof is adjusted to 50 parts by mass or less, thereby making it possible to improve the heat resistance of the cured film. Furthermore, the photosensitive resin composition according to the present invention may contain a sensitizer, if necessary.

The photosensitive resin composition according to the present invention contains the (D) colorant. The (D) colorant refers to an organic pigment, an inorganic pigment, or a dye commonly used in the field of electronic information materials. The (D) colorant is preferably an organic pigment and/or an inorganic pigment.

Examples of the organic pigment include diketopyrrolopyrrole-based pigments, azo-based pigments such as azo, disazo or polyazo, phthalocyanine-based pigments such as copper phthalocyanine, halogenated copper phthalocyanine, or metal-free phthalocyanine, anthraquinone-based pigments such as aminoanthraquinone, diaminodianthraquinone, anthrapyrimidine, flavanthrone, anthanthrone, indanthrone, pyranthrone, or violanthrone, quinacridone-based pigments, dioxazine-based pigments, perinone-based pigments, perylene-based pigments, thioindigo-based pigments, isoindoline-based pigments, isoindolinone-based pigments, quinophthalone-based pigments, threne-based pigments, benzofuranone-based pigments, or metal complex-based pigments.

Examples of the inorganic pigment include titanium oxide, zinc flower, zinc sulfide, lead white, calcium carbonate, precipitated barium sulfate, white carbon, alumina white, kaolin clay, talc, bentonite, black ferric oxide, cadmium red, red iron oxide, molybdenum red, molybdate orange, chrome vermillion, yellow lead, cadmium yellow, yellow ferric oxide, titanium yellow, chromium oxide, viridian, titanium cobalt green, cobalt green, cobalt chromium green, victoria green, ultramarine blue, Prussian blue, cobalt blue, cerulean blue, cobalt silica blue, cobalt zinc silica blue, manganese violet, or cobalt violet.

Examples of the dye include azo dyes, anthraquinone dyes, condensed polycyclic aromatic carbonyl dyes, indigoid dyes, carbonium dyes, phthalocyanine dyes, methine, or polymethine dyes.

Examples of a red pigment include pigment red 9, 48, 97, 122, 123, 144, 149, 166, 168, 177, 179, 180, 192, 209, 215, 216, 217, 220, 223, 224, 226, 227, 228, 240, or 254 (the numerical values all refer to color indexes (hereinafter “CI” numbers)).

Examples of an orange pigment include pigment orange 13, 36, 38, 43, 51, 55, 59, 61, 64, 65, or 71 (the numerical values all refer to CI numbers).

Examples of a yellow pigment include pigment yellow 12, 13, 17, 20, 24, 83, 86, 93, 95, 109, 110, 117, 125, 129, 137, 138, 139, 147, 148, 150, 153, 154, 166, 168, or 185 (the numerical values all refer to CI numbers).

Examples of a violet pigment include pigment violet 19, 23, 29, 30, 32, 37, 40, or 50 (the numerical values all refer to CI numbers).

Examples of a blue pigment include, pigment blue 15, 15: 3, 15: 4, 15: 6, 22, 60, or 64 (the numerical values all refer to CI numbers).

Examples of a green pigment include pigment green 7, 10, 36, or 58 (the numerical values all refer to CI numbers).

Examples of a black pigment include black organic pigments and black inorganic pigments. Examples of the black organic pigment include carbon black, a benzofuranone-based black pigment (described in the International Publication WO 2010/081624), a perylene-based black pigment, an aniline-based black pigment, or an anthraquinone-based black pigment. Among these pigments, in particular, the benzofuranone-based black pigment or the perylene-based black pigment is preferred in that a negative photosensitive resin composition is obtained which is more excellent in sensitivity. This is because the benzofuranone-based black pigment and the perylene-based black pigment are relatively high in transmittance in the ultraviolet region while achieving high light-shielding performance with low transmittances in the visible region, thereby causing the chemical reaction at the time of exposure to proceed efficiently. The benzofuranone-based black pigment and the perylene-based black pigment can also be contained together. Examples of the black inorganic pigment include graphite, or fine particles, oxides, composite oxides, sulfides, nitrides, or oxynitrides of metals such as titanium, copper, iron, manganese, cobalt, chromium, nickel, zinc, calcium, or silver, and carbon black or titanium nitride compounds is (are) preferred which has (have) high light-shielding performance.

Examples of a white pigment include titanium dioxide, barium carbonate, zirconium oxide, calcium carbonate, barium sulfate, alumina white, or silicon dioxide.

Examples of the dye can include Direct Red 2, 4, 9, 23, 26, 28, 31, 39, 62, 63, 72, 75, 76, 79, 80, 81, 83, 84, 89, 92, 95, 111, 173, 184, 207, 211, 212, 214, 218, 221, 223, 224, 225, 226, 227, 232, 233, 240, 241, 242, 243, or 247, Acid Red 35, 42, 51, 52, 57, 62, 80, 82, 111, 114, 118, 119, 127, 128, 131, 143, 145, 151, 154, 157, 158, 211, 249, 254, 257, 261, 263, 266, 289, 299, 301, 305, 319, 336, 337, 361, 396, or 397, Reactive Red 3, 13, 17, 19, 21, 22, 23, 24, 29, 35, 37, 40, 41, 43, 45, 49, or 55, Basic Red 12, 13, 14, 15, 18, 22, 23, 24, 25, 27, 29, 35, 36, 38, 39, 45, or 46, Direct Violet 7, 9, 47, 48, 51, 66, 90, 93, 94, 95, 98, 100, or 101, Acid Violet 5, 9, 11, 34, 43, 47, 48, 51, 75, 90, 103, or 126, Reactive Violet 1, 3, 4, 5, 6, 7, 8, 9, 16, 17, 22, 23, 24, 26, 27, 33, or 34, Basic Violet 1, 2, 3, 7, 10, 15, 16, 20, 21, 25, 27, 28, 35, 37, 39, 40, or 48, Direct Yellow 8, 9, 11, 12, 27, 28, 29, 33, 35, 39, 41, 44, 50, 53, 58, 59, 68, 87, 93, 95, 96, 98, 100, 106, 108, 109, 110, 130, 142, 144, 161, or 163, Acid Yellow 17, 19, 23, 25, 39, 40, 42, 44, 49, 50, 61, 64, 76, 79, 110, 127, 135, 143, 151, 159, 169, 174, 190, 195, 196, 197, 199, 218, 219, 222, or 227, Reactive Yellow 2, 3, 13, 14, 15, 17, 18, 23, 24, 25, 26, 27, 29, 35, 37, 41, or 42, Basic Yellow 1, 2, 4, 11, 13, 14, 15, 19, 21, 23, 24, 25, 28, 29, 32, 36, 39, or 40, Acid Green 16, Acid Blue 9, 45, 80, 83, 90, or 185, or Basic Orange 21 or 23 (the numerical values all refer to CI numbers), Sumilan, Lanyl (registered trademark) series (all manufactured by Sumitomo Chemical Industry Company Limited), Orasol (registered trademark), Oracet (registered trademark), Filamid (registered trademark), Irgasperse (registered trademark), Zapon, Neozapon, Neptune, Acidol series (all manufactured by BASF), Kayaset (registered trademark), Kayakalan (registered trademark) series (all manufactured by Nippon Kayaku Co., Ltd.), Valifast (registered trademark) Colors series (all manufactured by ORIENT CHEMICAL INDUSTRIES CO., LTD.), Savinyl, Sandoplast, Polysynthren (registered trademark), Lanasyn (registered trademark) series (all manufactured by Clariant Japan K.K.), Aizen (registered trademark), Spilon (registered trademark) series (all manufactured by Hodogaya Chemical Co., Ltd.), functional pigments (manufactured by Yamada Chemical Co., Ltd.), Plast Color, and Oil Color series (manufactured by ARIMOTO CHEMICAL Co., Ltd.).

For the purpose of improving the contrast of an organic EL display device, the color of the colorant is preferably a black color which can shield visible light over the entire wavelength range, and with the use of at least one or more selected from organic pigments, inorganic pigments, and dyes, such a colorant may be used which has a black color in the form of a cured film. To that end, the black organic pigment and black inorganic pigment described above may be used, or a pseudo black coloring may be obtained by mixing two or more organic pigments and dyes. In the case of pseudo black coloring, the coloring can be obtained by mixing two or more of the above-mentioned organic pigments such as red, orange, yellow, violet, blue, and green, and dyes. It is to be noted that there is not always a need for the photosensitive resin composition itself according to the present invention to be black in color, and such a colorant may be used which undergoes a color change at the time of curing by heating to cause the cured film to be black in color.

Among these colorants, from the viewpoint of being capable of ensuring high heat resistance, it is preferable to use such a colorant that contains an organic pigment and/or an inorganic pigment and has a black color in the form of a cured film. In addition, from the viewpoint of being capable of securing high insulation properties, it is preferable to use such a colorant that contains an organic pigment and/or a dye and has a black color in the form of a cured film. More specifically, from the viewpoint of being capable of achieving a balance between high heat resistance and insulation properties, it is preferable to use such a colorant that contains an organic pigment and has a black color in the form of a cured film.

The content of the (D) colorant is preferably 10 parts by mass or more, more preferably 20 parts by mass or more, further preferably 30 parts by mass or more, and preferably 300 parts by mass or less, more preferably 200 parts by mass or less, further preferably 150 parts by mass or less, with respect to 100 parts by mass of the (A) alkali-soluble resin. The content of the (D) colorant is adjusted to 10 parts by mass or more, thereby providing the colorability required for the cured film, and the content is adjusted to 300 parts by mass or less, thereby providing favorable storage stability.

The photosensitive resin composition according to the present invention preferably contains a (E) thermally crosslinking agent. The thermally crosslinking agent refers to a compound having at least two thermally reactive functional groups including a methylol group, an alkoxymethyl group, an epoxy group and an oxetanyl group in its molecule. The (E) thermally crosslinking agent is preferably contained, because the agent can make the (A) alkali-soluble resin or the other additive components cross-linked to enhance the chemical resistance and heat resistance of the cured film.

As the (E) thermally crosslinking agent, it is particularly preferable to contain a compound having 6 or more and 20 or less (E-1) methylol groups and/or alkoxymethyl groups in total. The number of methylol groups and/or alkoxymethyl groups is adjusted to 6 or more in total, thereby causing the crosslinking reaction to proceed at a relatively low temperature in the heat treatment step, and then providing a cured film which has a high crosslinking density. Thus, a cured film is obtained which is high in elastic modulus and high in hardness, and particle generation can be suppressed in bringing a deposition mask into contact with a pixel defining layer. On the other hand, the number of methylol groups and/or alkoxymethyl groups is adjusted to 20 or less in total, thereby allowing the storage stability of the photosensitive resin composition to be enhanced.

Examples of the (E-1) compound having 6 or more and 20 or less methylol groups and/or alkoxymethyl groups in total include the compound represented by the general formula (4), and a product of melamine modified with a methylol group and/or alkoxymethyl.

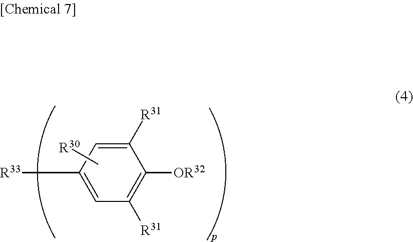

In the general formula (4), R³⁰ represents a hydrocarbon group having 1 to 6 carbon atoms, R³¹ represents CH₂OR³⁴ (R³⁴ represents a hydrogen atom or an organic group having 1 to 6 carbon atoms). Because of the excellent storage stability, R³⁴ is preferably a hydrocarbon group having 1 to 4 carbon atoms, and particularly preferably a methyl group or an ethyl group. R³² represents a hydrogen atom, a methyl group, or an ethyl group, and R³³ represents any of the groups listed below. p represents an integer of 3 or 4.

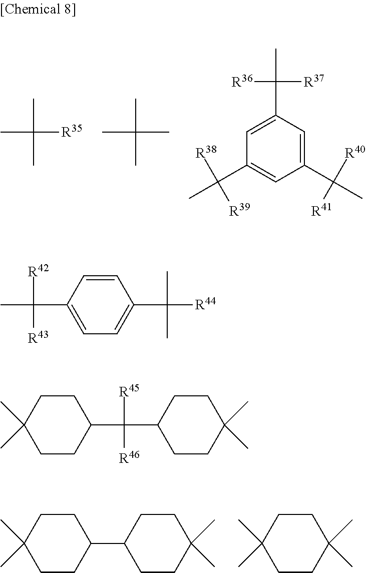

R³⁵ to R⁴⁶ each represent a hydrogen atom, an organic group having 1 to 20 carbon atoms, Cl, Br, I, F, or a fluoro-substituted organic group having 1 to 20 carbon atoms.

As the compound represented by the general formula (4), commercially available compounds can be used, and the compounds include HML-TPPHBA, HML-TPHAP, HMOM-TPPHBA, HMOM-TPHAP (trade names, manufactured by Honshu Chemical Industry Co., Ltd.).

As the product of melamine modified with a methylol group and/or alkoxymethyl, commercially available compounds can be used, and the compounds include NIKALAC (registered trademark, the same applies hereinafter), MW-100LM, NIKALAC MW-30HM (trade names, manufactured by SANWA CHEMICAL CO., LTD.), U-VAN (registered trademark, the same applies hereinafter) 228, U-VAN 2028 (trade names, manufactured by Mitsui Chemicals, Inc.).

As the (E) thermally crosslinking agent other than the (E-1) compound having 6 or more and 20 or less methylol groups and/or alkoxymethyl groups in total, examples of a compound having 2 or more and 5 or less methylol groups and/or alkoxymethyl groups in total include DML-PC, DML-PEP, DML-OC, DML-OEP, DML-34X, DML-PTBP, DML-PCHP, DML-OCHP, DML-PFP, DML-PSBP, DML-POP, DML-MBOC, DML-MBPC, DML-MTrisPC, DML-BisOC-Z, DML-BisOCHP-Z, DML-BPC, DML-BisOC-P, DMOM-PC, DMOM-PTBP, DMOM-MBPC, TriML-P, TriML-35XL, TML-HQ, TML-BP, TML-pp-BPF, TML-BPE, TML-BPA, TML-BPAF, TML-BPAP, TMOM-BP, TMOM-BPE, TMOM-BPA, TMOM-BPAF, and TMOM-BPAP (trade names, manufactured by Honshu Chemical Industry Co., Ltd.), NIKALAC (registered trademark, the same applies hereinafter) MX-290, NIKALAC MX-280, NIKALAC MX-270, and NIKALAC MX-279 (trade names, manufactured by SANWA CHEMICAL CO., LTD.).

Preferred examples of a compound having at least two epoxy groups include Epolite 40E, Epolite 100E, Epolite 200E, Epolite 400E, Epolite 70P, Epolite 200P, Epolite 400P, Epolite 1500NP, Epolite 80MF, Epolite 4000, and Epolite 3002 (manufactured by Kyoeisha Chemical Co., Ltd.), Denacol (registered trademark, the same applies hereinafter) EX-212L, Denacol EX-214L, Denacol EX-216L, Denacol EX-850L, and Denacol EX-321L (manufactured by Nagase ChemteX Corporation), GAN, GOT (manufactured by Nippon Kayaku Co., Ltd.), Epikote 828, Epikote 1002, Epikote 1750, Epikote 1007, YX8100-BH30, E1256, E4250, and E4275 (manufactured by Japan Epoxy Resin Co., Ltd.), EPICLON EXA-9583, HP4032, N695, and HP7200 (manufactured by DIC Corporation), VG3101 (manufactured by Mitsui Chemicals, Inc.), TEPIC (registered trademark, the same applies hereinafter) S, TEPIC G, and TEPIC P (manufactured by Nissan Chemical Corporation), NC6000 (manufactured by Nippon Kayaku Co., Ltd.), and EPOTOHTO YH-434L (manufactured by Tohto Kasei Co., Ltd.).

Preferred examples of a compound having at least two oxetanyl groups include ETERNACOLL (registered trademark, the same applies hereinafter) EHO, ETERNACOLL OXBP, ETERNACOLL OXTP, ETERNACOLL OXMA (manufactured by Ube Industries, Ltd.), and an oxetane derivative of phenol novolak.

For the (E) thermally crosslinking agent, two or more of the foregoing examples can be used in combination.

The content of the (E) thermally crosslinking agent is preferably 1 part by mass or more, more preferably 3 parts by mass or more with respect to 100 parts by mass of the (A) alkali-soluble resin. Further, the content is preferably 50 parts by mass or less, more preferably 30 parts by mass or less. The content of the thermally crosslinking agent is adjusted to 1 part by mass or more, thereby allowing the chemical resistance and hardness of the cured film to be enhanced, and the content is adjusted to 50 parts by mass or less, thereby making the storage stability of the photosensitive resin composition also excellent.

In the case of using a pigment as the colorant, the photosensitive resin composition according to the present invention preferably contains a (F) dispersant. Containing the (F) dispersant allows the colorant to be uniformly and stably dispersed in the resin composition. The (F) dispersant is not particularly limited, but a polymeric dispersant is preferred. Examples of the polymeric dispersant include a polyester-based polymeric dispersant, an acrylic based polymeric dispersant, a polyurethane-based polymeric dispersant, a polyallylamine-based polymeric dispersant, or a carbodiimide-based polymeric dispersant. More specifically, the polymeric dispersant refers to a polymer compound in which the main chain includes polyamino, polyether, polyester, polyurethane, polyacrylate, or the like, and the side chain or the main chain terminal has a polar groups such as amine, carboxylic acid, phosphoric acid, amine salt, carboxylate, phosphate, or the like. With the polar group adsorbed to the pigment, the steric hindrance of the main chain polymer serves to stabilize the pigment dispersion.

The (F) dispersant is classified into a (polymer) dispersant that has only an amine number, a (polymer) dispersant that has only an acid number, a (polymer) dispersant that has an amine number and an acid number, or a (polymer) dispersant that has neither amine number nor an acid number, and the (polymer) dispersant that has an amine number and an acid number and the (polymer) dispersant that has only an amine number are preferred, and the (polymer) dispersant that has only an amine number is more preferred.

Specific examples of the polymeric dispersant that has only an amine number include DISPERBYK (registered trademark) 102, 160, 161, 162, 2163, 164, 2164, 166, 167, 168, 2000, 2050, 2150, 2155, 9075, 9077, BYK-LP N6919, BYK-LP N 21116, or BYK-LP N 21234 (all manufactured by BYK-Chemie GmbH), EFKA (registered trademark) 4015, 4020, 4046, 4047, 4050, 4055, 4060, 4080, 4300, 4330, 4340, 4400, 4401, 4402, 4403, or 4800 (all manufactured by BASF), AJISPER (registered trademark) PB711 (manufactured by Ajinomoto Fine-Techno Co., Inc.), or SOLSPERSE (registered trademark) 13240, 13940, 20000, 71000, or 76500 (all manufactured by Lubrizol).

Among polymeric dispersants that have only an amine number, from the viewpoints of being capable of dispersing finer pigments and reducing the surface roughness of the cured film obtained from the photosensitive resin composition, that is, making the smoothness of the film surface favorable, polymeric dispersants are preferred which have, as a pigment adsorption group, a tertiary amino group or a basic functional group such as a nitrogen-containing heterocycle, e.g., pyridine, pyrimidine, pyrazine, or isocyanurate. Examples of the polymeric dispersant having a basic functional group of a tertiary amino group or a nitrogen-containing heterocycle include DISPERBYK (registered trademark) 164, 167, BYK-LP N6919, or BYK-LP N21116, or SOLSPERSE (registered trademark) 20000.

Examples of the polymeric dispersant that has an amine number and an acid number include DISPERBYK (registered trademark) 142, 145, 2001, 2010, 2020, 2025, or 9076, Anti-Terra (registered trademark)-205 (all manufactured by BYK-Chemie GmbH), AJISPER (registered trademark) PB821, PB880, or PB881 (all manufactured by Ajinomoto Fine-Techno Co., Inc.), or SOLSPERSE (registered trademark) 9000, 11200, 13650, 24000, 24000SC, 24000GR, 32000, 32500, 32550, 326000, 33000, 34750, 35100, 35200, 37500, 39000, or 56000 (all manufactured by Lubrizol).

The proportion of the dispersant to the colorant is preferably 1% by mass or more, more preferably 3% by mass or more, in order to improve the dispersion stability while maintaining the heat resistance. Further, the content is preferably 100% by mass or less, more preferably 50% by mass or less.

The photosensitive resin composition according to the present invention preferably contains an organic solvent. Examples of the organic solvent include compounds of ethers, acetates, esters, ketones, aromatic hydrocarbons, amides, or alcohols.

More specifically, examples thereof include ethers such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, dipropylene glycol dimethyl ether, dipropylene glycol methyl n-butyl ether, tripropylene glycol monomethyl ether, tripropylene glycol monoethyl ether, diethylene glycol dimethyl ether, diethylene glycol methyl ethyl ether, diethylene glycol diethyl ether, or tetrahydrofuran; acetates such as butyl acetate, ethylene glycol monomethyl ether acetate, ethylene glycol monoethyl ether acetate, propylene glycol monomethyl ether acetate, 3-methoxybutyl acetate, ethylene glycol monobutyl ether acetate, diethylene glycol monomethyl ether acetate, diethylene glycol monoethyl ether acetate, diethylene glycol monobutyl ether acetate, cyclohexanol acetate, propylene glycol diacetate, propylene glycol monomethyl ether acetate, propylene glycol monoethyl ether acetate (hereinafter “PGMEA”), dipropylene glycol methyl ether acetate, 3-methoxy-3-methyl-1-butyl acetate, 1,4-butanediol diacetate, 1,3-butylene glycol diacetate, or 1,6-hexanediol diacetate; ketones such as methyl ethyl ketone, cyclohexanone, 2-heptanone, or 3-heptanone; lactic acid alkyl esters such as methyl 2-hydroxypropionate or ethyl 2-hydroxypropionate; other esters such as ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanoate, 3-methoxybutyl acetate, 3-methyl-3-methoxybutyl acetate, 3-methyl-3-methoxybutyl propionate, ethyl acetate, n-propyl acetate, i-propyl acetate, n-butyl acetate, i-butyl acetate, n-pentyl formate, i-pentyl acetate, n-butyl propionate, ethyl butyrate, n-propyl butyrate, i-propyl butyrate, butyrate n-butyl, methyl pyruvate, ethyl pyruvate, n-propyl pyruvate, methyl acetoacetate, ethyl acetoacetate, or ethyl 2-oxobutanoate; aromatic hydrocarbons such as toluene or xylene; amides such as N-methylpyrrolidone, N,N-dimethylformamide, or N,N-dimethylacetamide; or alcohols such as butyl alcohol, and alcohols such as isobutyl alcohol, pentanol, 4-methyl-2-pentanol, 3-methyl-2-butanol, 3-methyl-3-methoxybutanol, or diacetone alcohol.

In a case where a pigment is used as the colorant, it is preferable to use a compound of acetates as the organic solvent in order to disperse and stabilize the pigment. The proportion of the compound of acetates to all of the organic solvents contained in the photosensitive resin composition according to the present invention is preferably 50% by mass or more, more preferably 70% by mass or more. Further, the proportion is preferably 100% by mass or less, more preferably 90% by mass or less.

Application with a die coating apparatus is becoming mainstream with the increase in substrate size, and in order to achieve preferred volatility and drying characteristics in the application, an organic solvent is preferred in which two or more compounds are mixed. In order to make the film thickness of the photosensitive resin film of the photosensitive resin composition according to the present invention uniform and make the smoothness and adhesiveness of the surface favorable, the proportion of a compound that has a boiling point of 120 to 180° C. to all of the organic solvents is preferably 30% by mass or more. Moreover, the proportion is preferably 95% by mass or less.

The proportion of the organic solvent to the total solid content of the photosensitive resin composition according to the present invention is preferably 50 parts by mass or more, more preferably 100 parts by mass or more with respect to 100 parts by mass of the total solid content. Further, the proportion is preferably 2000 parts by mass or less, and more preferably 1000 parts by mass or less.

The photosensitive resin composition according to the present invention can contain a chain transfer agent. Containing the chain transfer agent allows the cross-sectional shape of the film after curing by heating to be much less tapered. At the time of exposure, in the photosensitive resin composition according to the present invention, the radical generated from the photo initiator causes the (B) radically polymerizable compound to create a chain reaction and then polymerize, thereby causing the exposed part to be cured. The chain transfer agent receives radicals from the growing polymer chain and stops the extension of the polymer, but the chain transfer agent that receives the radicals can attack the monomers to initiate polymerization again. For this reason, containing the chain transfer agent allows the molecular weight of the polymer produced by the chain reaction of the (B) radically polymerizable compound to be kept relatively low, thereby allowing the film fluidity at the time of curing by heating to be enhanced, and thus allowing the cross-sectional shape of the film after the curing by heating to be made much less tapered.

Examples of the chain transfer agent can include a polyfunctional thiol. The polyfunctional thiol may be a compound having two or more thiol (SH) groups.

Examples of the polyfunctional thiol compound include ethylene glycol bisthiopropionate (EGTP), butanediol bisthiopropionate (BDTP), trimethylolpropane tristhiopropionate (TMTP), pentaerythritol tetrakisthiopropionate (PETP), tetraethylene glycol bis(3-mercapto propionate), dipentaerythritol hexakis(3-mercapto propionate), pentaerythritol tetrakis(thio glycolate), and Karenz (registered trademark, hereinafter the same applies) MT BD1, Karenz MTPE1, and Karenz MT NR1 (all manufactured by Showa Denko K.K.).

The content of the chain transfer agent is preferably 0.1 parts by mass or more, more preferably 0.5 parts by mass or more, with respect to 100 parts by mass of the (A) alkali-soluble resin. Further, the content is preferably 20 parts by mass or less, more preferably 10 parts by mass or less. The content of the chain transfer agent is adjusted to 0.1 parts by mass or more, thereby allowing the cross-sectional shape after the curing by heating to be made much less tapered, and the content is adjusted to 20 parts by mass or less, thereby allowing high heat resistance to be maintained.

The photosensitive resin composition according to the present invention can contain a polymerization terminator. The polymerization terminator refers to a compound capable of terminating radical polymerization by capturing a radical generated at the time of exposure, or a radical at the polymer growth terminal of the polymer chain obtained by radical polymerization at the time of exposure, and holding the radical as a stable radical.

Containing the polymerization terminator in an appropriate amount makes it possible to inhibit the generation of residues after development and improve the resolution after the development. This is presumed to be because the polymerization terminator captures an excessive amount of radical generated at the time of exposure or a radical at the growth terminal of the high-molecular-weight polymer chain, thereby keeping the radical polymerization from proceeding excessively.

As the polymerization terminator, a phenolic polymerization terminator is preferred. Examples of the phenolic polymerization terminator include 4-methoxyphenol, 1,4-hydroquinone, 1,4-benzoquinone, 2-t-butyl-4-methoxyphenol, 3-t-butyl-4-methoxyphenol, 4-t-butylcatechol, 2,6-di-t-butyl-4-methylphenol, 2,5-di-t-butyl-1,4-hydroquinone, or 2,5-di-t-amyl-1,4-hydroquinone, or IRGANOX (registered trademark) 1010, 1035, 1076, 1098, 1135, 1330, 1726, 1425, 1520, 245, 259, 3114, 565, 295 (all manufactured by BASF).

The content of the polymerization terminator is preferably 0.01 parts by mass or more, more preferably 0.03 parts by mass or more, with respect to 100 parts by mass of the (A) alkali-soluble resin. Further, the content is preferably 10 parts by mass or less, more preferably 5 parts by mass or less. The content of the polymerization terminator is adjusted to 0.01 parts by mass or more, thereby allowing the resolution after development to be improved, and the content is adjusted to 10 parts by mass or less, thereby allowing the sensitivity at the time of exposure to be kept high.

The photosensitive resin composition according to the present invention can contain an adhesion promoter. Examples of the adhesion promoter include silane coupling agents such as vinyltrimethoxysilane, vinyltriethoxysilane, epoxycyclohexylethyltrimethoxysilane, 3-glycidoxypropyltrimethoxysilane, 3-glycidoxypropyltriethoxysilane, p-styryltrimethoxysilane, 3-aminopropyltrimethoxysilane, 3-aminopropyltriethoxysilane, and N-phenyl-3-aminopropyltrimethoxysilane, titanium chelating agents, aluminum chelating agents, and a compound obtained by allowing an aromatic amine compound and an alkoxy group-containing silicon compound to undergo a reaction. Two or more of the examples may be contained. Containing the adhesion promoter allows, in such a case as developing a photosensitive resin film, the adhesion thereof to a silicon wafer or an underlying base material made of ITO, SiO₂, silicon nitride, or the like to be enhanced. Moreover, the resistance can be enhanced against oxygen plasma or UV ozone treatment for use in washing and the like. The content of the adhesion promoter is preferably 0.1 parts by mass or more, more preferably 0.3 parts by mass or more, with respect to 100 parts by mass of the (A) alkali-soluble resin. Further, the content is preferably 10 parts by mass or less, more preferably 5 parts by mass or less.

For the purpose of improving the wettability to a substrate, if necessary, the photosensitive resin composition according to the present invention may contain a surfactant. Commercially available compounds can be used as the surfactant, and specifically, examples of a silicone-based surfactant include a surfactant belonging to the SH series, SD series or ST series available from Dow Corning Toray Co., Ltd., the BYK series available from BYK Japan KK, the KP series available from Shin-Etsu Chemical Co., Ltd., the TSF series available from Momentive Performance Materials Inc., examples of a fluorine-based surfactant include a surfactant belonging to the “Megaface (registered trademark)” series available from DIC Corporation, the Fluorad series available from Sumitomo 3M Limited, the “Surflon (registered trademark)” series or “Asahi Guard (registered Lrademark)” series available from ASAHI GLASS CO., LTD., the EF series available from Shin Akita Chemicals Corporation or the PolyFox series available from OMNOVA Solutions, Inc., and examples of a surfactant composed of an acrylic-based polymer and/or a methacrylic-based polymer include a surfactant belonging to the POLYFLOW series available from Kyoeisha Chemical Co., Ltd. or the “DISPARLON (registered trademark)” series available from Kusumoto Chemicals, Ltd., but the surfactant is not limited thereto.

The content of the surfactant is preferably 0.001 parts by mass or more, more preferably 0.002 parts by mass or more, with respect to 100 parts by mass of the (A) alkali-soluble resin. Further, the content is preferably 1 part by mass or less, more preferably 0.5 parts by mass or less.

Next, a method for producing the photosensitive resin composition according to the present invention will be described. For example, the components (A) to (D) and, if necessary, the (E) thermally crosslinking agent, the (F) dispersant, the polymerization terminator, the thermally crosslinking agent, the adhesion promoter, the surfactant, and the like are dissolved in the organic solvent, thereby making it possible to obtain a photosensitive resin composition. Examples of the dissolution method include stirring and heating. In the case of heating, the heating temperature is preferably set within a range without impairing the performance of the resin composition, and typically to room temperature to 80° C. Further, the order of dissolving the respective components is not particularly limited, and there is, for example, a method of sequentially dissolving the compounds in the order of solubility from lowest to highest. In addition, components which are likely to generate air bubbles during dissolution with stirring, such as surfactants and some adhesion promoters, are added in the end after dissolving the other components, thereby making it possible to prevent the other components from being dissolved defectively due to the generation of air bubbles.

Moreover, in the case of using a pigment as the (D) colorant, examples thereof include a method of dispersing the colorant containing the pigment in the resin solution of the (A) component with the use of a disperser.

Examples of the disperser include a ball mill, a bead mill, a sand grinder, a triple roll mill, or a high-speed impact mill, but the bead mill is preferred for the purpose of enhancing the dispersion efficiency and fine dispersion. Examples of the bead mill include a co-ball mill, a basket mill, a pin mill, or a DYNO mill. Examples of the beads of the bead mill include titania beads, zirconia beads, or zircon beads. The bead size of the bead mill is preferably 0.01 mm or more, more preferably 0.03 mm or more. Further, the bead size is preferably 5.0 mm or less, more preferably 1.0 mm or less. In a case where the colorant is small in primary particle size, and the secondary particle formed by aggregation of the primary particles is small in particle size, fine beads of 0.03 mm or more and 0.10 mm or less are preferred. In this case, a bead mill is preferred which is provided with a separator capable of separating minute beads and a dispersion by a centrifugal separation method.

On the other hand, in the case of dispersing a colorant including submicron coarse particles, beads of 0.10 mm or more are preferred because sufficient grinding power is obtained.

The obtained resin composition is preferably filtered with the use of a filtration filter to remove dust and particles. The filter pore size is, for example, 0.5 μm, 0.2 μm, 0.1 μm, 0.05 μm, or the like, but is not limited thereto. The material of the filtration filter may be polypropylene (PP), polyethylene (PE), nylon (NY), polytetrafluoroethylene (PTFE), and the like, and polyethylene and nylon are preferred. In a case where the photosensitive resin composition contains therein a pigment, it is preferable to use a filtration filter with a pore size larger than the particle size of the pigment.

Next, a method for producing a cured film with the use of the photosensitive resin composition according to the present invention will be described in detail. The method for producing a cured film includes:

(1) a step of applying the photosensitive resin composition described above to a substrate to form a photosensitive resin film;
(2) a step of drying the photosensitive resin film; (3) a step of exposing the dried photosensitive resin film through a photomask;
(4) a step of developing the exposed photosensitive resin film; and
(5) a step of applying a heat treatment to the developed photosensitive resin film.

In the step of forming the photosensitive resin film, the photosensitive resin composition according to the present invention is applied by a spin coating method, a slit coating method, a dip coating method, a spray coating method, a printing method, or the like to obtain a photosensitive resin film of the photosensitive resin composition. Prior to the application, a base material to which the photosensitive resin composition is applied may be subjected to a pretreatment in advance with the above-described adhesion promoter. Examples of the pretreatment include a method of treating the base material surface with the use of a solution prepared by dissolving an adhesion promoter in a content of 0.5 to 20% by mass in a solvent such as isopropanol, ethanol, methanol, water, tetrahydrofuran, propylene glycol monomethyl ether acetate, propylene glycol monomethyl ether, ethyl lactate, and diethyl adipate. Examples of the method for the treatment of the base material surface include methods such as spin coating, slit die coating, bar coating, dip coating, spray coating, and steaming.

In the step of drying the photosensitive resin film, the applied photosensitive resin film is subjected to a reduced pressure drying treatment, if necessary, and thereafter, subjected to a heat treatment for 1 minute to several hours in the range of 50° C. to 180° C. with the use of a hot plate, an oven, infrared rays, or the like to obtain a photosensitive resin film.

Next, the step of exposing the dried photosensitive resin film through a photomask will be described. The photosensitive resin film is irradiated with actinic rays through the photomask which has a desired pattern. Examples of the actinic rays used for the exposure include ultraviolet rays, visible light rays, electron rays, and X rays, and in the present invention, it is preferable to use i-line (365 nm), h-line (405 nm), or g-line (436 nm) from a mercury lamp. After the irradiation with the actinic rays, post-exposure baking may be performed. By performing the post-exposure baking, effects can be expected, such as an improved resolution after development or increased tolerance for development conditions. The post-exposure baking can use an oven, a hot plate, infrared rays, a flash annealing device, a laser annealing device, or the like. The post-exposure baking temperature is preferably 50 to 180° C., more preferably 60 to 150° C. The post-exposure baking time is preferably 10 seconds to several hours. When the post-exposure baking time falls within the range mentioned above, the reaction may proceed favorably, thereby shortening the development time.

In the step of developing the exposed photosensitive resin film to form a pattern, the exposed photosensitive resin film is developed with the use of a developer to remove the film other than the exposed part. As the developer, an aqueous solution of a compound that exhibits alkalinity, such as tetramethylammonium hydroxide, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine, and hexamethylenediamine, is preferred. Moreover, in some cases, these aqueous alkali solutions may have polar solvents such as N-methyl-2-pyrrolidone, N,N-dimethylformamide, N,N-dimethylacetamide, dimethyl sulfoxide, γ-butyrolactone, and dimethylacrylamide; alcohols such as methanol, ethanol, and isopropanol; esters such as ethyl lactate and propylene glycol monomethyl ether acetate; ketones such as cyclopentanone, cyclohexanone, isobutyl ketone, and methyl isobutyl ketone, and the like added alone or in combination. As a developing method, a method is possible, such as spray, paddle, immersion, or ultrasonic.

Next, the pattern formed by the development is preferably subjected to a rinsing treatment with distilled water. Also in this regard, the rinsing treatment may be performed with the addition of alcohols such as ethanol and isopropyl alcohol, esters such as ethyl lactate and propylene glycol monomethyl ether acetate, or the like to the distilled water.

Next, the step of applying a heat treatment to the developed photosensitive resin film is performed. Since the residual solvent, and components which are low in heat resistance can be removed by the heating treatment, the heat resistance and the chemical resistance can be improved. In a case where the photosensitive resin composition according to the present invention contains a polyimide precursor, a polybenzoxazole precursor, and/or a copolymer thereof, an imide ring or an oxazole ring can be formed by the heat treatment, and the heat resistance and chemical resistance can be thus improved. Furthermore, in the case of containing the thermally crosslinking agent, the heat treatment can cause a thermally crosslinking reaction to proceed, and thus improve the heat resistance and the chemical resistance. This heating treatment is performed for 5 minutes to 5 hours while selecting temperature levels and gradually increasing the temperature, or while selecting a certain temperature range and continuously increasing the temperature. As an example, the heat treatment is performed at each of 150° C. and 250° C. for 30 minutes. Alternatively, examples thereof include a method of linearly increasing the temperature over 2 hours from room temperature up to 300° C. The heat treatment condition in the present invention is preferably 180° C. or higher, more preferably 200° C. or higher, further preferably 230° C. or higher, particularly preferably 250° C. or higher. In addition, the heat treatment condition is preferably 400° C. or lower, more preferably 350° C. or lower, and further preferably 300° C. or lower.

In the method for producing a cured film with the use of the photosensitive resin composition according to the present invention, it is preferable to use a half-tone photomask as the photomask.

The half-tone photomask refers to, for example, a photomask that has a pattern including a light-transmitting portion 16 and a light-blocking portion 15 as shown in FIG. 3, the photomask having, between the light-transmitting portion 16 and the light-blocking portion 15, a partial-transmitting portion 14 that is lower in transmittance than the value of the light-transmitting portion 16 and higher in transmittance than the value of the light-blocking portion 15. The exposure with the use of the half-tone photomask makes it possible to form a pattern which has a step shape after development and after thermal curing. It is to be noted that the cured part irradiated with active actinic rays through the light-transmitting portion corresponds to the thick film part, whereas the half-tone exposed part irradiated with active actinic rays through the partial-transmitting portion corresponds to the thin film part.

As the half-tone photomask, in a case where the transmittance of the light-transmitting portion is denoted by (% T_{FT}), the transmittance (% T_{HT}) of the partial-transmitting portion is preferably 10% or more of (% T_{FT}), more preferably 15% or more thereof, further preferably 20% or more thereof, particularly preferably 25% or more thereof. When the transmittance (% T_{HT}) of the partial-transmitting portion falls within the range mentioned above, the exposure energy at the time of the formation of the cured pattern which has the step shape can be reduced, thus allowing the cycle time to be shortened. On the other hand, the transmittance (% T_{HT}) of the partial-transmitting portion is preferably 60% or less of (% T_{FT}), more preferably 55% or less thereof, further preferably 50% or less thereof, particularly preferably 45% or less thereof. When the transmittance (% T_{HT}) of the partial-transmitting portion falls within the range mentioned above, the film thickness difference between the thick film part and the thin film part and the film thickness difference between adjacent thin film parts on both sides of any step can be made sufficiently large, thus allowing degradation of the light-emitting element to be suppressed.

The method for producing a cured film with the use of the photosensitive resin composition according to the present invention may use, as a photomask, two or more photomasks that differ in the area of the light-transmitting portion.

The divided exposure twice or more with the use of two or more photomasks that differ in the area of the light-transmitting portion makes it possible to form two or more exposed parts corresponding to a cured part and a half-tone exposed part in the case of using a half-tone photomask. Thus, it becomes possible to form a cured film that has a step shape.

FIG. 1 shows a cross section example of a cured film which has a step shape with the number of steps being two, obtained from the photosensitive resin composition according to the present invention. On a substrate 1, a cured film 2 which has a step shape is formed, and a thick film part 3 corresponds to the area of a light-transmitting portion in the case of exposure through the half-tone photomask, and has the maximum film thickness of the cured pattern. On the other hand, thin film parts 4 and 5 correspond to the area of a partial-transmitting portion in the case of expose through the half-tone photomask, and have a smaller film thickness than the thickness of the thick film part 3.

The inclination angles of the substrate 1 and the thin film parts 4 and 5 of the cured film are respectively represented by taper angles θ_{A} and θ_{D}, and the inclination angles of the thin film parts 4 and 5 of the cured film and the thick film part 3 are respectively represented by taper angles θ_{B} and θ_{C}. The θ_{A}, θ_{B}, θ_{C}, and θ_{D} are preferably 60° or less, more preferably 50° or less, further preferably 40° or less in that an electric field is kept from being concentrated on edge parts of electrodes, and preferably 5° or more, further preferably 10° or more in that organic EL display elements can be disposed at a high density.

The number of steps of the cured film which has a step shape, obtained from the photosensitive resin composition according to the present invention, is two or more, preferably five or less, more preferably four or less, further preferably three or less. When the number of steps falls within the range mentioned above, the film thickness difference between the thick film part and the thin film part and the film thickness difference between adjacent thin film parts on both sides of any step can be made sufficiently large, thus allowing the area of contact with an evaporation mask in the formation of a light-emitting layer to be made small, and thus, it is possible to suppress the decrease in panel yield due to the generation of particles, and it is possible to suppress degradation of the light-emitting element. In this regard, for example, if the number of steps is three, there will be a thick film part with the maximum film thickness, a thin film part with a film thickness smaller than the maximum film thickness, and a thin film part with a much smaller film thickness.

In a case where the film thickness of the thick film part 3 of the cured film 2 which has a step shape, obtained from the photosensitive resin composition according to the present invention, is denoted by (T_{FT}) μm, the film thickness of the thin film part 4 thereof is denoted by (T_{HT}) μm, and the film thickness difference between the film thickness (T_{FT}) of the thick film part 3 and the film thickness (T_{HT}) of the thin film part 4 is denoted by (ΔT_{FT-HT}) μm, the (T_{FT}), the (T_{HT}), and the (ΔT_{FR-HT}) preferably satisfy the relations represented by the formulas (α) to (γ).

In this regard, the film thickness (T_{FT}) of the thick film part 3 refers to the film thickness of the thickest part of the thick film part 3, and the film thickness of the thin film part 4 refers to the average film thickness of the part which is horizontal to the substrate with the thin film part 4. Further, the part which is horizontal to the substrate refers to a region where the inclination angle to the substrate is 3° or less. It is to be noted that in a case where the number of steps is three or more, all of the thin film parts satisfy the relations represented by the formulas (α) to (γ).

1.0≤(T_{FT})≤5.0 (α)

0.2≤(T_{HT})≤4.0 (β)

0.5≤(ΔT_{FT-HT})≤4.0 (γ)

The film thickness (T_{FT}) of the thick film part is preferably 1.0 μm or more, more preferably 1.2 μm or more, further preferably 1.5 μm or more, particularly preferably 1.7 μm or more, most preferably 2.0 μm or more. When the film thickness (T_{FT}) of the thick film part falls within the range mentioned above, it is easy to secure the film thickness difference from the thin film part. On the other hand, the film thickness (T_{FT}) of the thick film part is preferably 5.0 μm or less, more preferably 4.5 μm or less, further preferably 4.0 μm or less, particularly preferably 3.5 μm or less, most preferably 3.0 μm or less. When the film thickness (T_{FT}) of the thick film part falls within the range mentioned above, the film thickness of the photosensitive resin film can be reduced, and the exposure energy can be thus reduced, thereby allowing the cycle time to be shortened.

The film thickness (T_{HT}) of the thin film part 4 disposed with at least one step shape interposed for the thick film part 3 is preferably 0.2 μm or more, more preferably 0.3 μm or more, further preferably 0.5 μm or more, particularly preferably 0.7 μm or more, most preferably 1.0 μm or more. When the film thickness (T_{HT}) of the thin film part falls within the range mentioned above, a sufficient film thickness can be secured as a pixel defining layer, and defects of the organic EL elements can be prevented, such as an abnormal light emission due to insufficient insulation. On the other hand, the film thickness (T_{HT}) of the thin film part 4 is preferably 4.0 μm or less, more preferably 3.5 μm or less, further preferably 3.0 μm or less, particularly preferably 2.5 μm or less, most preferably 2.0 μm or less. When the film thickness (T_{HT}) of the thin film part falls within the range mentioned above, it is easy to secure the film thickness difference from the thick film part.

The film thickness difference (ΔT_{FT-HT}) μm between the film thickness (T_{FT}) of the thick film part and the film thickness (T_{HT}) of the thin film part is preferably 0.5 μm or more, more preferably 0.7 μm or more, further preferably 1.0 μm or more, particularly preferably 1.2 μm or more, most preferably 1.5 μm or more. When the film thickness difference between the film thickness of the thick film part and the film thickness of the thin film part falls within the range mentioned above, the contact between an evaporation mask and the thin film part of the pixel defining layer in the formation of a light-emitting layer can be prevented, and the decrease in panel yield due to particle generation can be thus suppressed. On the other hand, film thickness difference (ΔT_{FT-HT}) μm between the film thickness of the thick film part and the film thickness of the thin film part is preferably 4.0 μm or less, more preferably 3.5 μm or less, further preferably 3.0 μm or less, particularly preferably 2.5 μm or less, most preferably 2.0 μm or less. When the film thickness difference between the film thickness of the thick film part and the film thickness of the thin film part falls within the range mentioned above, the film thickness of the photosensitive resin film can be reduced, and the exposure energy can be thus reduced, thereby allowing the cycle time to be shortened.

The proportion of the thick film part to the whole area of the cured film obtained from the photosensitive resin composition according to the present invention is preferably 5% or more, more preferably 7% or more, further preferably 10% or more, particularly preferably 12% or more, most preferably 15% or more. The area of the thick film part herein refers to the area of the region indicated by the thick film part 3 in FIG. 1, that is, the total of the region horizontal to the substrate and the region inclined with respect to the substrate. When the proportion of the area of the thick film part falls within the range mentioned above, the area of contact between a sealing part such as cover glass and the thick film part of the pixel defining layer can be sufficiently secured in the organic EL display device, and the mechanical strength can be thus enhanced. On the other hand, the proportion of the thick film part to the whole area of the cured film is preferably 50% or less, more preferably 45% or less, further preferably 40% or less, particularly preferably 35% or less, most preferably 30% or less. When the proportion of the area of the thick film part falls within the range mentioned above, the contact between an evaporation mask and the thin film part of the pixel defining layer in the formation of a light-emitting layer can be prevented, and the decrease in panel yield due to particle generation can be thus suppressed. The cured film obtained from the photosensitive resin composition according to the present invention is preferably used as a planarization layer and a pixel defining layer in display device including a substrate with a T_{FT} formed, the planarization layer on a driving circuit, the pixel defining layer on a first electrode, and a display element in this order. More specifically, the planarization layer and/or the pixel defining layer constitute an element that has the cured film. Examples of the thus configured display device include a liquid crystal display and an organic EL display device. The cured film is particularly preferably used for, among the examples, the organic EL display device required to have high heat resistance and low outgassing for the planarization layer and the pixel defining layer. The cured film of the cured photosensitive resin composition according to the present invention may be used for only one of the planarization layer and the pixel defining layer, or may be used for the both, but is particularly preferably used, in particular, for the pixel defining layer required to have a step shape. More specifically, the photosensitive resin composition according to the present invention is preferably used for collectively forming the step shape of the pixel defining layer in the organic EL display device.

In addition, the photosensitive resin composition according to the present invention contains the (D) colorant, thus allowing electrode wiring to be prevented from becoming visible or allowing external light reflection to be reduced, and the contrast in image display can be thus improved. Accordingly, the use of the cured film obtained from the photosensitive resin composition according to the present invention as the pixel defining layer of the organic EL display device can improve the contrast, without forming any polarizing plate and a quarter wavelength plate on the light extraction side of the light-emitting element.

The cured film obtained from the photosensitive resin composition according to the present invention is, in optical density (OD value) with a thickness of 1.0 μm, preferably 0.3 or more, more preferably 0.5 or more, further preferably 1.0 or more, and preferably 3.0 or less, more preferably 2.5 or less, further preferably 2.0 or less. The optical density is adjusted to 0.3 or more, thereby making it possible to contribute to the improved contrast of the display device, and the optical density is adjusted to 3.0 or less, thereby making it possible to reduce residues in pattern openings.

The cured film obtained from the photosensitive resin composition according to the present invention preferably has an indentation elastic modulus of 7.0 GPa or more, more preferably 7.5 GPa or more, further preferably 8.0 GPa or more, and preferably 12.0 GPa or less, more preferably 11.0 GPa or less, further preferably 10.0 GPa or less. The indentation elastic modulus is adjusted to fall within the range described above, thereby making it possible to improve the scratch resistance of the cured film, and in the case of using the cured film for the pixel defining layer of the organic EL display device, making it possible to suppress particle generation in bringing an evaporation mask into contact with the pixel defining layer. The indentation elastic modulus is calculated by a nanoindentation method in accordance with ISO 14577. The measurement is made on the thick film part of the cured film. Preferable examples of the measurement conditions can include the following method.

With the use of a nano indentation tester ENT-2100 manufactured by ELIONIX INC. as a measurement device, and a Berkovich indenter (triangular pyramid, dihedral angle: 115°) as an indenter, the measurement is made with the number of tests n=5 at a measurement temperature of 25° C., and the average value is calculated. The maximum test load is applied under such a condition that the indentation depth of the indenter is 10% or less of the thickness of the cured film. This is because if the indentation depth exceeds 10%, the indentation elastic modulus of the cured film will be inaccurate under the influence of the underlying base material.

An active matrix-type display device has, on a substrate such as glass, a T_{FT} and a wiring located at the lateral side of the T_{FT} and connected to the T_{FT}, and has a planarization layer thereon to cover recesses and protrusions, furthermore, with a display element provided on the planarization layer. The display element and the wiring are connected through a contact hole formed in the planarization layer.

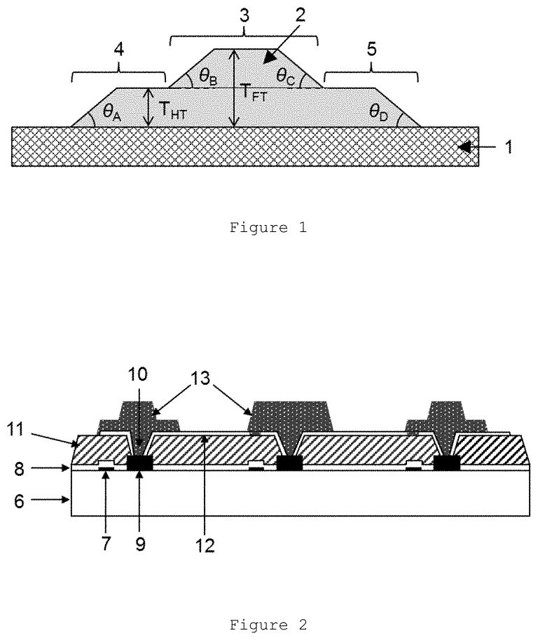

FIG. 2 shows a sectional view of a T_{FT} substrate with a planarization layer and a pixel defining layer formed. On a substrate 6, bottom gate-type or top gate-type TFTs 7 are provided in a matrix form, and a T_{FT} insulation film 8 is formed in a manner that covers the TFTs 7. Moreover, a wiring 9 connected to the T_{FT} 7 is provided under the T_{FT} insulation film 8. Furthermore, on the T_{FT} insulation film 8, contact holes 10 that are opened to the wirings 9 are provided, and a planarization layer 11 is provided in a manner that embeds the holes. In the planarization layer 11, openings are provided so as to reach the contact holes 10 for the wirings 9. Further, an electrode 12 is formed on the planarization layer 11 to be connected to the wirings 9 through the contact holes 10. In this regard, the electrode 12 serves as an electrode of a display element (for example, an organic EL element). Further, a pixel defining layer 13 is formed so as to cover the peripheral edge of the electrode 12. This organic EL element may be a top emission-type element where emitted light is emitted from the side opposite to the substrate 6, or may be a bottom emission-type element where light is extracted from the substrate 6.

### EXAMPLES

The present invention will be described with reference to examples and the like, but the present invention is not to be considered limited by these examples. It is to be noted that the photosensitive resin compositions in EXAMPLES were evaluated by the following methods.

(1) Average Molecular Weight Measurement

The molecular weights of resins (P1) to (P4) used in the examples were measured with the use of a GPC (gel permeation chromatography) device Waters 2690-996 (manufactured by Nihon Waters K.K.) and N-methyl-2-pyrrolidone (hereafter, referred to as NMP) as a developing solvent, and the number average molecular weights (Mn) were calculated in terms of polystyrene.

(2) Film Thickness Measurement

With the use of a surface texture and contour measuring instrument (SURFCOM 1400D; TOKYO SEIMITSU CO., LTD.), at the measurement magnification of 10,000 times, the measurement length of 1.0 mm, the measurement speed of 0.30 mm/s, the film thickness was measured after prebaking, after development, and after curing.

(3) Sensitivity Evaluation

The photosensitive resin composition according to each example was applied onto an OA-10 glass plate (manufactured by Nippon Electric Glass Co., Ltd.) by a spin coating method at an arbitrary number of revolutions to obtain a photosensitive resin film, and the photosensitive resin film was subjected to, as a drying step, prebaking for 2 minutes on a hot plate at 100° C. to obtain a photosensitive resin film of 3.5 μm in film thickness. Next, the photosensitive resin film was, with the use of a double-sided alignment—single-sided exposure system (Mask Aligner PEM-6M; manufactured by Union Optical Co., Ltd.), subjected to pattern exposure with i-line (wavelength: 365 nm), h-line (wavelength: 405 nm), and g-line (wavelength: 436 nm) of an ultrahigh pressure mercury lamp through a gray scale mask (photomask) for sensitivity measurement. Thereafter, the exposed photosensitive resin film was subjected to shower development with a 2.38% by mass tetramethylammonium hydroxide aqueous solution for 90 seconds with the use of an automatic development device (AD-2000 manufactured by Takizawa Sangyo K. K.), and then rinsed with pure water for 30 seconds. The pattern of the developed photosensitive resin film, developed by the foregoing method, was observed at a 50-fold magnification with the use of an FDP microscope MX61 (manufactured by Olympus Corporation), and the exposure energy for forming a 20 μm line-and-space pattern at 1:1 in width (referred to as optimum exposure energy) was determined, and regarded as the sensitivity.

(4) Sectional Shape Evaluation of Cured Film

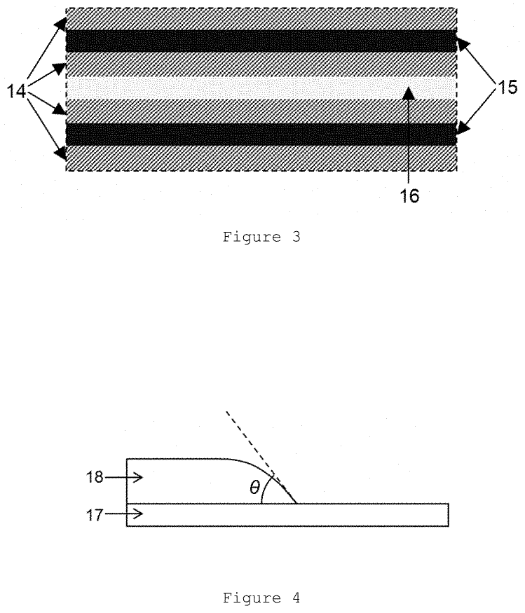

The substrate with the developed photosensitive resin film, obtained in the (3) Sensitivity evaluation, was subjected to curing (heat treatment) for 60 minutes in an oven at 250° C. under a nitrogen atmosphere to obtain a cured film. The sectional shape of the 20 μm pattern line of the cured film obtained was observed with the use of a scanning electron microscope (“S-4800 type” manufactured by Hitachi, Ltd.), among the angles made by a substrate 17 and slopes of an insulation layer 18 in FIG. 4, the largest angle was regarded as a taper angle θ, and the value of θ was measured.

(5) Step Shape Evaluation of Cured Film

The photosensitive resin composition according to each example was applied onto an OA-10 glass plate (manufactured by Nippon Electric Glass Co., Ltd.) by a spin coating method at an arbitrary number of revolutions, and subjected to prebaking for 2 minutes on a hot plate at 100° C. to obtain a film of 3.5 μm in film thickness. Next, the photosensitive resin film was, with the use of a double-sided alignment—single-sided exposure system (Mask Aligner PEM-6M; manufactured by Union Optical Co., Ltd.), subjected to pattern exposure by the optimum exposure energy obtained in the (3) Sensitivity evaluation, with i-line (wavelength: 365 nm), h line (wavelength: 405 nm), and g line (wavelength: 436 nm) of an ultrahigh pressure mercury lamp through a half-tone photomask including the light-transmitting portion 16 and light-blocking portion 15 shown in FIG. 3, with a transmittance of 30% in the partial-transmitting portion 14. The line width of the half-tone photomask used was 12 μm for each of the partial-transmitting portion 14, the light-blocking portion 15, and the light-transmitting portion 16. Thereafter, the film was subjected to shower development with a 2.38% by mass tetramethylammonium hydroxide aqueous solution for 90 seconds with the use of an automatic development device (AD-2000 manufactured by Takizawa Sangyo K. K.), and then rinsed with pure water for 30 seconds. Next, the obtained substrate with the developed photosensitive resin film was subjected to curing in an oven under a nitrogen atmosphere under the following three conditions:

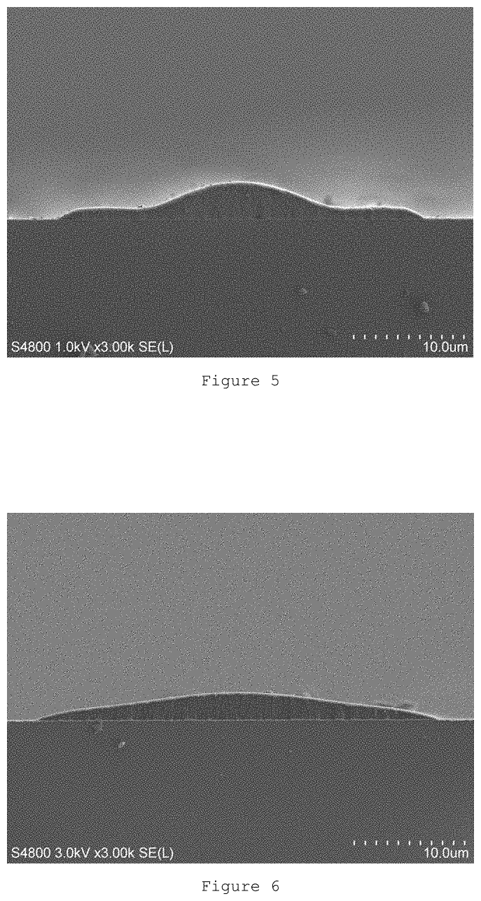

Condition 1: 250° C./60 minutes
Condition 2: 270° C./60 minutes
Condition 3: 300° C./60 minutes
The sectional shape of the obtained cured film was observed with the use of a scanning electron microscope (“S-4800 type” manufactured by Hitachi, Ltd.), and the sectional shape with a step shape obtained, where a region with an inclination angle of 3° or less to the substrate was included in a thin film part was determined to be “favorable”, whereas the sectional shape with a step shape lost due to pattern flow at the time of curing, where a region with an inclination angle of 3° or less to the substrate was not included in a thin film part was determined to be “defective”. FIG. 5 shows a “favorable” example with a step shape obtained, and FIG. 6 shows a “defective” example with a step shape lost. The “favorable” example under all of the conditions 1 to 3 was determined to be A, the “favorable” example under only the conditions 1 and 2 was determined to be B, the “favorable” example under only the condition 1 was determined to be C, and the “defective” example under all of the conditions was determined to be D.

(6) Film Thickness Evaluation of Cured Film with Step Shape

In the cured film obtained by the curing under the condition 1 in the (5) Step shape evaluation of cured film, the film thickness (T_{FT}) of the thick film part, the film thickness (T_{HT}) of the thin film part, and the film thickness difference (ΔT_{FT-HT}) between the thick film part and the thin film part were measured by the method described in the (2) Film thickness measurement. However, the measurement was achieved only when the “favorable” step shape was obtained in the (5) Step shape evaluation of cured film, or otherwise, the film thicknesses were determined to be unmeasurable.

(7) Pattern Dimension Change Between Before and after Curing

In the cured film preparation step of the (5) Step shape evaluation of cured film, in a case where the pattern dimension of the opening after the development was denoted by (CD_{DEV}), whereas the pattern dimension of the same part after the curing under the condition 1 was denoted by (CD_{CURE}), the amount of change in pattern size (CD_{DEV}−CD_{CURE}) between after the development and after the curing was measured at 50-fold magnification with the use of an FDP microscope MX61 (manufactured by Olympus Corporation).

(8) Evaluation of Indentation Elastic Modulus of Cured Film

The indentation elastic modulus of the cured film obtained in the (4) Sectional Shape Evaluation of Cured Film was measured with the number of measurements n=5 under the following conditions with the use of the nano indentation tester ENT-2100 (manufactured by ELIONIX INC.), and the average value was calculated.

Indenter shape: Berkovich
Loading speed: 0.02 mN/s
Maximum test load: 0.1 mN
Maximum test load holding time: 10 seconds
Unloading speed: 0.02 mN/s
Measurement temperature: 25° C.

(9) Evaluation of Water Absorption of Cured Film

The photosensitive resin composition according to each example was applied onto a 6-inch silicon wafer whose weight W₀ had been measured in advance, by a spin coating method at an arbitrary number of revolutions to obtain a photosensitive resin film, and the photosensitive resin film was subjected to, as a drying step, prebaking for 2 minutes on a hot plate at 100° C. to obtain a photosensitive resin film of 3.5 μm in film thickness. Next, the obtained substrate with the photosensitive resin film was, with the use of a double-sided alignment—single-sided exposure system (Mask Aligner PEM-6M; manufactured by Union Optical Co., Ltd.), subjected to entire exposure by the optimum exposure energy obtained in the (3) Sensitivity Evaluation, with i-line (wavelength: 365 nm), h line (wavelength: 405 nm), and g line (wavelength: 436 nm) of an ultrahigh pressure mercury lamp through a gray scale mask (photomask) for sensitivity measurement. Thereafter, the substrate with the exposed photosensitive resin film was subjected to shower development with a 2.38% by mass tetramethylammonium hydroxide aqueous solution for 90 seconds with the use of an automatic development device (AD-2000 manufactured by Takizawa Sangyo K. K.), and then rinsed with pure water for 30 seconds. Next, the substrate with the developed photosensitive resin film was subjected to curing (heat treatment) for 60 minutes in an oven at 250° C. under a nitrogen atmosphere to obtain the substrate with a cured film. After measuring the weight W₁ of the obtained substrate with the cured film, the substrate was immersed in ultrapure water for 24 hours under the condition of 23° C. After taking out the substrate from the ultrapure water, moisture adhering to the substrate with the cured film was sufficiently wiped off, and the weight W₂ was then measured. Then, water absorption was determined by the following formula (X).

Water Absorption=(W₂−W₁)/(W₁−W₀)×100 Formula (X).

(10) Evaluation of optical density of cured film With the use of an optical densitometer (361T Visual; manufactured by X-Rite Inc.), the incident light intensity and transmitted light intensity onto and from the cured film obtained under the condition 1 (250° C./60 minutes) in the (5) Step shape evaluation of cured film were each measured, and the light-blocking OD value was calculated from the following formula (Y).

OD value=log₁₀(I₀/I) Formula (Y)

I₀: incident light intensity
I: transmitted light intensity.

(11) Organic EL Display Characteristics

<Method for Producing Organic EL Display Device>

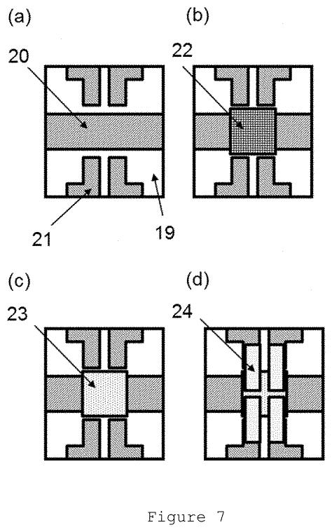

FIGS. 7(a) to 7(d) are schematic views of an organic EL display device used. First, ITO transparent conductive coatings of 10 nm was formed by sputtering on the entire surface of a 38×46 mm non-alkali glass substrate 19, and etched to form a first electrode 20, and at the same time, an auxiliary electrode 21 was also formed for extracting a second electrode. The obtained substrate was subjected to ultrasonic washing with “Semico Clean 56” (trade name, manufactured by Furuuchi Chemical Corporation) for 10 minutes, and then washed with ultrapure water. Next, the photosensitive resin composition according to each example was applied by a spin coating method to the entire surface of the substrate, and subjected to prebaking for 2 minutes on a hot plate at 100° C. to form a film. This film was subjected to UV exposure through a photomask, and then subjected to development with a 2.38% TMAH aqueous solution to dissolve only the exposed part, and then rinsed with pure water to obtain a pattern. The obtained pattern was subjected to curing for 60 minutes in an oven at 250° C. under a nitrogen atmosphere. In this way, openings of 70 μm in width and 260 pun in length were arranged at a pitch of 155 μm in the width direction and a pitch of 465 μm in the length direction, and a pixel defining layer 22 in a shape for exposing the first electrode through the respective openings was formed only on a substrate effective area in a limited fashion. It is to be noted that the openings will finally serve for light-emitting pixels. Further, the substrate effective area was a square of 16 mm on a side, and the thickness of the pixel defining layer was about 1.0 μm.

Next, an organic EL display device was prepared with the use of the non-alkali glass substrate 19 with the first electrode 20, the auxiliary electrode 21, and the pixel defining layer 22 formed. After the substrate was subjected to a nitrogen plasma treatment as a pretreatment, an organic EL layer 23 including a light-emitting layer was formed by vacuum deposition. It is to be noted that the degree of vacuum for the deposition was 1×10⁻³ Pa or less, and during the deposition, the substrate was rotated with respect to a deposition source. First, a compound (HT-1) of 10 nm and a compound (HT-2) of 50 nm were deposited respectively as a hole injection layer and a hole transport layer. Next, for the light-emitting layer, a compound (GH-1) as a host material and a compound (GD-1) as a dopant material were deposited to have a thickness of 40 nm, in such a way that the dope concentration reached 10% in volume ratio. Next, as an electron transport material, a compound (ET-1) and LiQ were laminated at a volume ratio of 1:1 to have a thickness of 40 nm. Here are the structures of the compounds used for the organic EL layer 23.

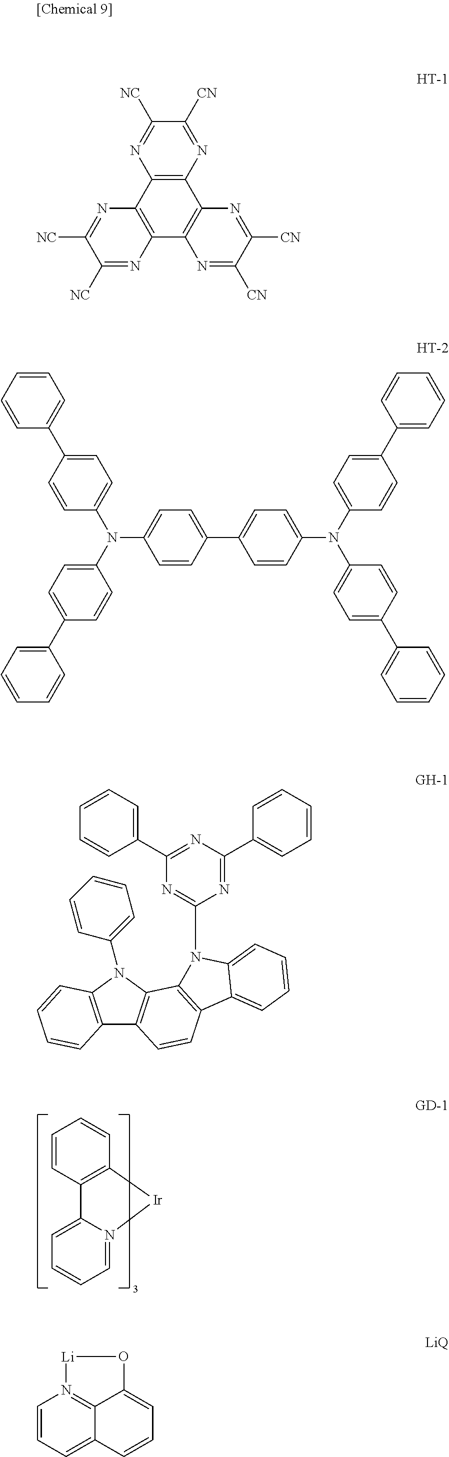

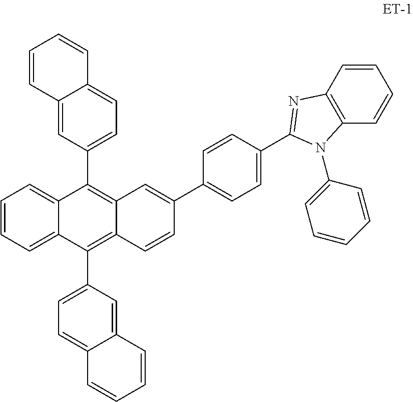 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

Next, after LiQ of 2 nm was deposited, Mg and Ag were deposited for 10 nm at a volume ratio of 10:1 to provide a second electrode 24. Finally, under a low-humidity nitrogen atmosphere, sealing was performed by bonding a cap-shaped glass plate with the use of an epoxy resin-based adhesive, and four light-emitting devices each in a square shape of 5 mm on a side were prepared on one substrate. It is to be noted that the film thickness herein refers to a value displayed on a crystal oscillation-type film thickness monitor.

<Evaluation of Initial Light Emission>

The organic EL display device prepared by the method described above was driven with a direct current at 10 mA/cm² to emit light, and it was confirmed whether there were abnormal light-emitting characteristics such as no light emission, uneven luminance, or reduced light-emitting area.

<Durability Evaluation>

The organic EL display device prepared by the method described above was subjected to a durability test of holding at 80° C. for 500 hours, and then driven with direct current at 10 mA/cm² to emit light, and it was confirmed whether there were abnormal light-emitting characteristics such as no light emission, uneven luminance, or reduced light-emitting area.

Here are the compounds used in Examples and Comparative Examples.

### (A) Alkali-Soluble Resin

### Synthesis Example 1 Synthesis of Hydroxyl Group-Containing Diamine Compound

In a mixture of 100 mL of acetone and 17.4 g (0.3 mol) of propylene oxide, 18.3 g (0.05 mol) of 2,2-bis(3-amino-4-hydroxyphenyl)hexafluoropropane (hereinafter, referred to as BAHF) was dissolved, and the solution was cooled to −15° C. Into this solution, a solution of 20.4 g (0.11 mol) of 3-nitrobenzoyl chloride dissolved in 100 mL of acetone was added dropwise. After the completion of dropping, the solution was allowed to undergo a reaction for 4 hours at −15° C., and then, the temperature thereof was returned to room temperature. The precipitated white solid matter was filtered off, and subjected to vacuum dry at 50° C.

In a 300-mL stainless steel autoclave, 30 g of the solid matter was put, and dispersed in 250 mL of methyl cellosolve, and 2 g of 5% palladium-carbon was added to the dispersion. With hydrogen introduced thereinto through a balloon, and the dispersion was allowed to undergo a reduction reaction at room temperature. After about 2 hours, it was confirmed that the balloon was no longer deflated, and the reaction was terminated. After the termination of the reaction, the palladium compound as a catalyst was removed by filtration, and the reaction solution was concentrated through a rotary evaporator to obtain a hydroxyl group-containing diamine compound represented by the following formula.

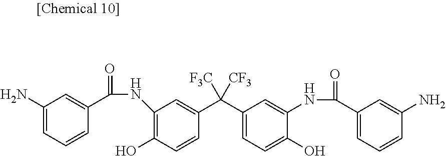 [SMILES: Nc1cccc(C(=O)Nc2cc(C(c3ccc(O)c(NC(=O)c4cccc(N)c4)c3)(C(F)(F)F)C(F)(F)F)ccc2O)c1]

### Synthesis Example 2 Synthesis of Alkali-Soluble Resin (P1)

Under a stream of dry nitrogen, 58.6 g (0.16 mol) of BAHF and 8.7 g (0.08 mol) of 3-aminophenol as an end-capping agent were dissolved in 300 g of N-methyl-2-pyrrolidone (NMP). To this solution, 62.0 g (0.20 mol) of ODPA was added together with 100 g of NMP, and the solution was stirred for 1 hour at 20° C. and then stirred for 4 hours at 50° C. Thereafter, 15 g of xylene was added thereto, and the solution was stirred for 5 hours at 150° C. while azeotroping the water with the xylene. After the completion of the stirring, the solution was put into 5 L of water to collect a white precipitate. The precipitate was collected by filtration, washed three times with water, and then dried for 24 hours in a vacuum drying machine at 80° C. to obtain the target polyimide (P1). The number average molecular weight of the polyimide (P1) was 8200.

### Synthesis Example 3 Synthesis of Alkali-Soluble Resin (P2)

Under a stream of dry nitrogen, 62.0 g (0.20 mol) of 3,3′,4,4′-diphenyl ether tetracarboxylic acid dianhydride (hereinafter, referred to as ODPA) was dissolved in 500 g of N-methyl-2-pyrrolidone (hereinafter, referred to as NMP). To this solution, 96.7 g (0.16 mol) of the hydroxyl group-containing diamine compound obtained in Synthesis Example 1 was added together with 100 g of NMP, and the solution was allowed to undergo a reaction for 1 hour at 20° C., and then allowed to undergo a reaction for 2 hours at 50° C. Next, 8.7 g (0.08 mol) of 3-aminophenol as an end-capping agent was added thereto together with 50 g of NMP, and the solution was allowed to undergo a reaction for 2 hours at 50° C. Thereafter, a solution of 47.7 g (0.40 mol) of N,N-dimethylformamide dimethylacetal diluted with 100 g of NMP was added dropwise thereinto over a period of 10 minutes. After dropping, the solution was stirred for 3 hours at 50° C. After the completion of the stirring, the solution was cooled to room temperature, and then, the solution was put into 5 L of water to obtain a white precipitate. The precipitate was collected by filtration, washed three times with water, and then dried for 24 hours in a vacuum drying machine at 80° C. to obtain the target polyimide precursor (P2). The number average molecular weight of the polyimide precursor (P2) was 11000.

### Synthesis Example 4 Synthesis of Alkali-Soluble Resin (P3)

Under a stream of dry nitrogen, 0.16 mol of a dicarboxylic acid derivative mixture obtained by reacting 41.3 g (0.16 mol) of diphenyl ether-4,4′-dicarboxylic acid with 43.2 g (0.32 mol) of 1-hydroxy-1,2,3-benzotriazole, and 73.3 g (0.20 mol) of BAHF were dissolved in 570 g of NMP, and then allowed to undergo a reaction at 75° C. for 12 hours. Next, 13.1 g (0.08 mol) of 5-norbornene-2,3-dicarboxylic acid anhydride dissolved in 70 g of NMP was added thereto, and the reaction was terminated by further stirring for 12 hours. After filtering the reaction mixture, the reaction mixture was put into a solution of water/methanol=3/1 (volume ratio) to obtain a white precipitate. The precipitate was collected by filtration, washed three times with water, and then dried for 24 hours in a vacuum drying machine at 80° C. to obtain the target polybenzoxazole (PBO) precursor (P3). The number average molecular weight of the PBO precursor (P3) was 8500.

### Synthesis Example 5 Synthesis of Alkali-Soluble Resin (P4)

A methyl methacrylate/methacrylic acid/styrene copolymer (mass ratio 30/40/30) was synthesized by a known method (Japanese Patent No. 3120476; Example 1). With respect to 100 parts by mass of the copolymer, 40 parts by mass of glycidyl methacrylate was added, and through reprecipitation with purified water, filtration, and drying, an acrylic resin (P4) was obtained as a polymer containing a radically polymerizable monomer with a weight average molecular weight (Mw) of 15000 and an acid number of 110 (mgKOH/g).

### Synthesis Example 6 Synthesis of Photo Acid Generator

Under a stream of dry nitrogen, 21.22 g (0.05 mol) of TrisP-PA (trade name, manufactured by Honshu Chemical Industry Co., Ltd.) and 36.27 g (0.135 mol) of 5-naphthoquinonediazide sulfonyl chloride were dissolved in 450 g of 1,4-dioxane, and the solution was allowed to stand at room temperature. To this solution, 15.18 g of triethylamine mixed with 50 g of 1,4-dioxane was added dropwise so as to keep the temperature in the system from reaching 35° C. or higher. After dropping, the solution was stirred for 2 hours at 30° C. The triethylamine salt was filtered off, and the filtrate was put into water. Thereafter, the separated-out precipitate was collected by filtration. The precipitate was dried in a vacuum drying machine to obtain a photo acid generator represented by the following formula.

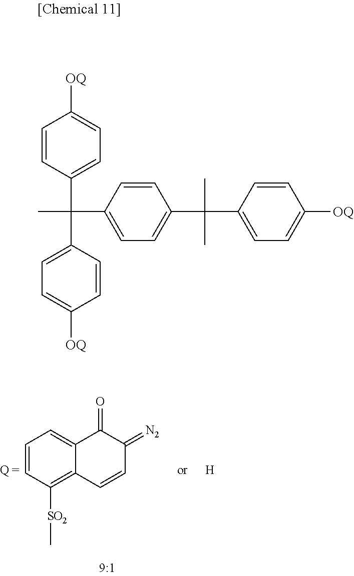

Other alkali-soluble resin V259ME; PGMEA solution of cardo resin (solid content concentration: 56.5% by mass, manufactured by New Nippon Steel Chemical Co., Ltd.).

### (B) Radically Polymerizable Compound

ADDM; of 1,3-adamantane dimethacrylate (manufactured by Mitsubishi Gas Chemical Company, Inc.), Tg of homopolymer: 245 [° C.], the number of functional groups: 2
DCP-A; “Light Acrylate” (registered trademark) DCP-A (dimethylol tricyclodecane diacrylate, manufactured by Kyoeisha Chemical Co., Ltd.), Tg of homopolymer: 190 [° C.], the number of functional groups: 2
DCP-M; Light Ester DCP-M (dimethylol tricyclodecane dimethacrylate, manufactured by Kyoeisha Chemical Co., Ltd.), Tg of homopolymer: 214 [° C.], the number of functional groups: 2
DPCA-60; “KAYARAD” (registered trademark) DPCA-60 (caprolactone-modified dipentaerythritol hexaacrylate having 6 pentylene carbonyl structures in the molecule, manufactured by Nippon Kayaku Co., Ltd.), Tg of homopolymer: 60 [° C.], the number of functional groups: 6
DPHA; “KAYARAD” (registered trademark) DPHA (dipentaerythritol hexaacrylate, manufactured by Nippon Kayaku Co., Ltd.), Tg of homopolymer: 80 [° C.], the number of functional groups: 6
M-315; “ARONIX” (registered trademark) M-315 (isocyanuric acid ethylene oxide modified triacrylate, manufactured by Toagosei Co., Ltd.), Tg of homopolymer: 272 [° C.], the number of functional groups: 3
PE-4A; “Light Acrylate” (registered trademark) PE-4A (pentaerythritol tetraacrylate, manufactured by Kyoeisha Chemical Co., Ltd.), Tg of homopolymer: 103 [OC], the number of functional groups: 4.

### (C) Photo Initiator

NCI-831: “ADEKA ARKLS” (registered trademark) NCI-831 (oxime ester-based photo initiator, manufactured by ADEKA Corporation).

### (D) Colorant

BLACK S0084; “IRGAPHOR” (registered trademark) BLACK S0084 (perylene-based black pigment, manufactured by BASF)
BLACK S0100CF; “IRGAPHOR” (registered trademark) BLACK S0100CF (benzofuranone-based black pigment, manufactured by BASF)
D. Y. 201; C. I. Disperse Yellow 201 (yellow dye)
P. B. 15: 6; C. I. Pigment Blue 15: 6 (blue pigment)
P. R. 254; C. I. Pigment Red 254 (red pigment)
P. Y. 139; C. I. Pigment Yellow 139 (yellow pigment)
S. B. 63; C. I. Solvent Blue 63 (blue dye)
S. R. 18; C. I. Solvent Red 18 (red dye)
TPK-1227; carbon black (manufactured by CABOT) surface-treated for introducing a sulfonic acid group.

### (E) Thermally Crosslinking Agent

HMOM-TPHAP; (compound having six methoxymethyl groups, manufactured by Honshu Chemical Industry Co., Ltd.)
MW-100-LM; “NIKALAC” (registered trademark) MW-100-LM (compound having six methoxymethyl groups, manufactured by NIPPON CARBIDE INDUSTRIES CO., INC.)
MX-270; “NIKALAC” (registered trademark) MX-270 (compound having four methoxymethyl groups, manufactured by NIPPON CARBIDE INDUSTRIES CO., INC.)
VG3101L; “TECHMORE” (registered trademark) VG3101L (compound having three epoxy groups, manufactured by Printec Corporation).

### (F) Dispersant

S-20000; “SOLSPERSE” (registered trademark) 20000 (polyether-based dispersant, manufactured by Lubrizol).

<Solvent>

GBL; γ-butyrolactone
MBA; 3-methoxybutyl acetate.

### Adjustment of Pigment Dispersion

### Preparation Example 1

As an alkali-soluble resin, 117 g of MBA as a solvent was weighed and mixed with 33.3 g of (P1) obtained in Synthesis Example 2, thereby providing a resin solution. In this resin solution, 33.3 g of SOLSPERSE 20000 as a dispersant, 828 g of MBA as a solvent, and 100 g of Irgaphor Black S0100CF as a colorant are weighed and mixed, and with the use of a high-speed disperser (HomoDisper 2.5 type; manufactured by PRIMIX Corporation), stirred for 20 minutes to obtain a preliminary dispersion. In Ultra Apex Mill (UAM-015; manufactured by Kotobuki Industries Co., Ltd.) equipped with a centrifugal separator filled with 75% of 0.30 mm diameter zirconia grinding balls (YTZ; manufactured by Tosoh Corporation) as ceramic beads for pigment dispersion, the prepared preliminary dispersion was supplied, and treated for 3 hours at a rotor peripheral speed of 7.0 m/s to obtain a pigment dispersion (Dsp-1) with solid content concentration of 15% by mass, and colorant/resin=60/40 (mass ratio).

### Preparation Examples 2 to 8

Dispersions Dsp-2 to 8 were obtained by the same method as in Preparation Example 1, with the types and amounts of compounds as listed in Table 1.

TABLE 1

| | | (A) | | | |
|---|---|---|---|---|---|
| | Pigment | Alkali- | | (F) | |
| | disper- | soluble | (D) | Disper- | Sol- |
| | sion | resin | Colorant | sant | vent |
| Preparation | Dsp-1 | P1 | BLACK S0100CF | S-20000 | MBA |
| Example 1 | | 33.3 g | 100 g | 33.3 g | 945 g |
| Preparation | Dsp-2 | P2 | BLACK S0100CF | S-20000 | MBA |
| Example 2 | | 33.3 g | 100 g | 33.3 g | 945 g |
| Preparation | Dsp-3 | P3 | BLACK S0100CF | S-20000 | MBA |
| Example 3 | | 33.3 g | 100 g | 33.3 g | 945 g |
| Preparation | Dsp-4 | P4 | BLACK S0100CF | S-20000 | MBA |
| Example 4 | | 33.3 g | 100 g | 33.3 g | 945 g |
| Preparation | Dsp-5 | V259ME | BLACK S0100CF | S-20000 | MBA |
| Example 5 | | 33.3 g | 100 g | 33.3 g | 945 g |
| Preparation | Dsp-6 | P1 | BLACK S0084 | S-20000 | MBA |
| Example 6 | | 33.3 g | 100 g | 33.3 g | 945 g |
| Preparation | Dsp-7 | P1 | TPK1227 | S-20000 | MBA |
| Example 7 | | 33.3 g | 100 g | 33.3 g | 945 g |
| Preparation | Dsp-8 | P1 | P.B.15:6/P.R.123/ | S-20000 | MBA |
| Example 8 | | | P.Y.192 | | |
| | | 33.3 g | 50 g/35 g/15 g | 33.3 g | 945 g |

### Example 1

Under yellow light, 8.0 g of the (P1) obtained in Synthesis Example 2 as the (A) alkali-soluble resin, 3.0 g of DCP-M and 3.0 g of DPCA-60 as the (B) radically polymerizable compound, 1.5 g of NCI-831 as the (C) photo initiator, and 2.0 g of MW-100-LM as the (E) thermally crosslinking agent were weighed, and with 99.1 g of MBA added thereto, stirred and dissolved to obtain a preliminarily prepared liquid. Next, 66.7 g of the pigment dispersion (Dsp-1) obtained in Preparation Example 1 was weighed, and with the obtained preliminarily prepared liquid added thereto, stirred to obtain a homogeneous solution. In this regard, the (P1) as the (A) alkali-soluble resin, BLACK S0100 CF as the (D) colorant, S-20000 as the (F) dispersant, and MBA, contained in the weighed pigment dispersion (Dsp-1), are respectively 2.0 g, 6.0 g, 2.0 g, and 56.7 g. Thereafter, the obtained solution was filtered with a filter of 1 μm in pore size to obtain a photosensitive resin composition A. The above-described evaluations of (3) to (10) were performed with the use of the obtained photosensitive resin composition.

### Examples 2 to 15, 17 to 20, Comparative Examples 1 to 4

Photosensitive resin compositions B to P and R to U and photosensitive resin compositions a to d were obtained by the same method as in Example 1, with the types and amounts of compounds as listed in Tables 2 to 4. The above-described evaluations of (3) to (10) were performed with the use of the obtained photosensitive resin composition.

### Example 16

Under yellow light, 10.0 g of the (P1) obtained in Synthesis Example 2 as the (A) alkali-soluble resin, 3.0 g of DCP-M and 3.0 g of DPCA-60 as the (B) radically polymerizable compound, 1.5 g of NCI-831 as the (C) photo initiator, 3.0 g of a dye S. B. 63, 2.0 g of a dye S.R. 18, and 1.0 g of a dye D.Y. 201 as the colorant (D), and 2.0 g of MW-100-LM as the (E) thermally crosslinking agent were weighed, and with 144.5 g of GBL added thereto, stirred and dissolved. Thereafter, the obtained solution was filtered with a filter of 1 μm in pore size to obtain a photosensitive resin composition Q. The above-described evaluations of (3) to (10) were performed with the use of the obtained photosensitive resin composition.

### Comparative Example 5

Under yellow light, 10.0 g of the (P1) obtained in Synthesis Example 2 as the (A) alkali-soluble resin, 3.0 g of a dye S. B. 63, 2.0 g of a dye S.R. 18, and 1.0 g of a dye D.Y. 201 as the colorant (D), 2.0 g of MW-100-LM as the (E) thermally crosslinking agent, and furthermore, 1.5 g of the photo acid generator obtained in Synthesis Example 6 were weighed, and with 102.0 g of GBL added thereto, stirred and dissolved. Thereafter, the obtained solution was filtered with a filter of 1 μm in pore size to obtain a photosensitive resin composition e. The above-described evaluations of (3) to (10) were performed with the use of the obtained photosensitive resin composition.

The evaluation results of Examples and Comparative Examples are shown in Tables 2 to 4.

TABLE 2

Example

| | | | | | 1 | 2 | 3 | 4 | 5 | 6 | 7 | 8 | 9 |
|---|---|---|---|---|---|---|---|---|---|---|---|---|---|
| Photosensitive resin composition | | | | | A | B | C | D | E | F | G | H | I |
| Used pigment dispersion | | | | | DSP- | DSP- | DSP- | DSP- | DSP- | DSP- | DSP- | DSP- | DSP- |
| | | | | | 1 | 1 | 1 | 1 | 1 | 1 | 1 | 1 | 1 |
| Composition | (A) Component | | P1 (polyimide) | | 100 | 100 | 100 | 100 | 100 | 100 | 100 | 100 | 100 |
| (parts by mass) | | | P2 (polyimide | | | | | | | | | | |
| | | | precursor) | | | | | | | | | | |
| | | | P3 (PBO | | | | | | | | | | |
| | | | precursor) | | | | | | | | | | |
| | (B) | (B-1) | DCP-M | Tg = 214 | 30 | | | | 30 | 30 | 30 | 30 | 30 |
| | Component | | | [° C.] | | | | | | | | | |
| | | | DCP-A | Tg = 190 | | 30 | | | | | | | |
| | | | | [° C.] | | | | | | | | | |
| | | | ADDM | Tg = 245 | | | 30 | | | | | | |
| | | | | [° C.] | | | | | | | | | |
| | | | M-315 | Tg = 272 | | | | 30 | | | | | |
| | | | | [° C.] | | | | | | | | | |
| | | (B-2) | DPCA-60 | Tg = 60 | 30 | 30 | 30 | 30 | | | 30 | 30 | 30 |
| | | | | [° C.] | | | | | | | | | |
| | | | DPHA | Tg = 80 | | | | | 30 | | | | |
| | | | | [° C.] | | | | | | | | | |
| | | | PE-4A | Tg = 103 | | | | | | 30 | | | |
| | | | | [° C.] | | | | | | | | | |

| Tg of (B) component as a polymer [° C.] | | | 123 | 114 | 132 | 140 | 136 | 151 | 123 | 123 | 123 |
|---|---|---|---|---|---|---|---|---|---|---|---|
| (C) Component | | NCI-831 | 15 | 15 | 15 | 15 | 15 | 15 | 15 | 15 | 15 |
| (D) | Pigment | BLACK S0100CF | 60 | 60 | 60 | 60 | 60 | 60 | 60 | 60 | 60 |
| Component | | | | | | | | | | | |
| (E) | (E-1) | MW-100-LM | 20 | 20 | 20 | 20 | 20 | 20 | | | |
| Component | | HMOM-TP-HAP | | | | | | | 20 | | |
| | Other | MX-270 | | | | | | | | 20 | |
| | | VG3101L | | | | | | | | | 20 |

| | | | | | | | | | | |
|---|---|---|---|---|---|---|---|---|---|---|
| (F) Component | S-20000 | 20 | 20 | 20 | 20 | 20 | 20 | 20 | 20 | 20 |
| Solvent | MBA | 1558 | 1558 | 1558 | 1558 | 1558 | 1558 | 1558 | 1558 | 1558 |

| | | | Example | | | | | | | | |
|---|---|---|---|---|---|---|---|---|---|---|---|
| | | | 1 | 2 | 3 | 4 | 5 | 6 | 7 | 8 | 9 |
| Evaluation | Photosensitive | Sensitivity | 55 | 75 | 55 | 90 | 90 | 110 | 90 | 60 | 70 |
| results | characteristics | [mJ/cm²] | | | | | | | | | |
| | Cured film | Taper angle | 37 | 35 | 42 | 46 | 28 | 28 | 38 | 32 | 35 |
| | characteristics | θ [°] | | | | | | | | | |
| | | Step shape | A | B | A | A | A | A | A | A | A |
| | | Thickness of | 2.7 | 2.5 | 2.8 | 2.5 | 2.5 | 2.3 | 2.5 | 2.7 | 2.7 |
| | | thick film | | | | | | | | | |
| | | part T_{FT} [μm] | | | | | | | | | |
| | | Thickness of | 1.2 | 0.9 | 1.0 | 0.6 | 1.1 | 0.8 | 0.8 | 1.2 | 1.0 |
| | | thin film | | | | | | | | | |
| | | part T_{HT} [μm] | | | | | | | | | |
| | | Film | 1.5 | 1.6 | 1.8 | 1.9 | 1.4 | 1.5 | 1.7 | 1.5 | 1.7 |
| | | thickness | | | | | | | | | |
| | | difference | | | | | | | | | |
| | | ΔT_{FT-HT} [μm] | | | | | | | | | |
| | | Dimension | <0.1 | <0.1 | <0.1 | <0.1 | 0.3 | 0.5 | <0.1 | 0.4 | 0.5 |
| | | change [μm] | | | | | | | | | |
| | | Water | 0.8 | 1.1 | 0.8 | 1.4 | 0.8 | 0.8 | 0.9 | 0.8 | 0.7 |
| | | absorption [%] | | | | | | | | | |
| | | Indentation | 8.0 | 7.8 | 8.2 | 7.6 | 8.3 | 8.0 | 8.3 | 6.7 | 6.7 |
| | | elastic | | | | | | | | | |
| | | modulus [GPa] | | | | | | | | | |
| | Optical | Optical | 1.0 | 1.0 | 1.0 | 1.0 | 1.0 | 1.0 | 1.0 | 1.0 | 1.0 |
| | characteristics | density (OD) | | | | | | | | | |
| | Organic EL | Evaluation of | Favor- | Favor- | Favor- | Favor- | Favor- | Favor- | Favor- | Favor- | Favor- |
| | display | initial light | able | able | able | able | able | able | able | able | able |
| | characteristics | emission | | | | | | | | | |
| | | Durability | Favor- | Favor- | Favor- | Favor- | Favor- | Favor- | Favor- | Favor- | Favor- |
| | | evaluation | able | able | able | able | able | able | able | able | able |

TABLE 3

| | | | | | Example | | | | | | | |
|---|---|---|---|---|---|---|---|---|---|---|---|---|
| | | | | | 10 | 11 | 12 | 13 | 14 | 15 | 16 | 17 |
| Photosensitive resin composition | | | | | J | K | L | M | N | O | P | Q |
| Used pigment dispersion | | | | | DSP- | DSP- | DSP- | DSP- | DSP- | DSP- | DSP- | DSP- |
| | | | | | 1 | 1 | 2 | 3 | 6 | 7 | 8 | 1 |
| Composition | (A) Component | | P1 (polyimide) | | 100 | | | 100 | 100 | 100 | 100 | 100 |
| (parts by mass) | | | P2 (polyimide | | | 100 | | | | | | |
| | | | precursor) | | | | | | | | | |
| | | | P3 (PBO precursor) | | | | 100 | | | | | |
| | (B) | (B-1) | DCP-M | Tg = 214 | 30 | 30 | 30 | 30 | 30 | 30 | 30 | 12 |
| | Component | | | [° C.] | | | | | | | | |
| | | (B-2) | DPCA-60 | Tg = 60 | 30 | 30 | 30 | 30 | 30 | 30 | 30 | |
| | | | | [° C.] | | | | | | | | |
| | | | DPHA | Tg = 80 | | | | | | | | 48 |
| | | | | [° C.] | | | | | | | | |

| Tg of (B) component as a polymer [° C.] | | | 123 | 123 | 123 | 123 | 123 | 123 | 123 | 101 |
|---|---|---|---|---|---|---|---|---|---|---|
| (C) Component | | NCI-831 | 15 | 15 | 15 | 15 | 15 | 15 | 15 | 15 |
| (D) | Pigment | BLACK S0100CF | 60 | 60 | 60 | | | | | 60 |
| Component | | BLACK S0084 | | | | 60 | | | | |
| | | TPK-1227 | | | | | 30 | | | |
| | | P.B.15:6 | | | | | | 40 | | |
| | | P.R.123 | | | | | | 30 | | |
| | | P.Y.192 | | | | | | 30 | | |
| | Dye | S.B.63 | | | | | | | 30 | |
| | | S.R.18 | | | | | | | 20 | |
| | | D.Y.201 | | | | | | | 10 | |
| (E) | (E-1) | MW-100-LM | | 20 | 20 | 20 | 20 | 20 | 20 | 20 |
| Component | | | | | | | | | | |

| | | | | | | | | | |
|---|---|---|---|---|---|---|---|---|---|
| (F) Component | S-20000 | 20 | 20 | 20 | 20 | 20 | 20 | | 20 |
| Solvent | MBA | 1445 | 1558 | 1558 | 1558 | 1388 | 1785 | | 1558 |
| | GBL | | | | | | | 1445 | |

| | | | Example | | | | | | | |
|---|---|---|---|---|---|---|---|---|---|---|
| | | | 10 | 11 | 12 | 13 | 14 | 15 | 16 | 17 |
| Evaluation | Photosensitive | Sensitivity | 70 | 45 | 60 | 70 | 120 | 40 | 40 | 80 |
| results | characteristics | [mJ/cm²] | | | | | | | | |
| | Cured film | Taper angle | 30 | 33 | 35 | 37 | 45 | 35 | 35 | 25 |
| | characteristics | θ [°] | | | | | | | | |
| | | Step shape | A | A | A | A | A | A | A | C |
| | | Thickness of | 2.6 | 2.8 | 2.6 | 2.7 | 2.5 | 2.8 | 2.7 | 2.4 |
| | | thick film | | | | | | | | |
| | | part T_{FT} [μm] | | | | | | | | |
| | | Thickness of | 0.9 | 1.0 | 0.9 | 1.2 | 1.0 | 1.2 | 1.0 | 0.6 |
| | | thin film | | | | | | | | |
| | | part T_{HT} [μm] | | | | | | | | |
| | | Film | 1.7 | 1.8 | 1.7 | 1.5 | 1.5 | 1.6 | 1.7 | 1.8 |
| | | thickness | | | | | | | | |
| | | difference | | | | | | | | |
| | | ΔT_{FT-HT} [μm] | | | | | | | | |
| | | Dimension | 0.8 | <0.1 | <0.1 | <0.1 | <0.1 | <0.1 | <0.1 | 0.3 |
| | | change [μm] | | | | | | | | |
| | | Water | 0.8 | 0.9 | 0.8 | 0.8 | 0.8 | 0.8 | 0.8 | 1.1 |
| | | absorption [%] | | | | | | | | |
| | | Indentation | 6.3 | 8.2 | 8.0 | 8.1 | 8.4 | 7.8 | 8.0 | 8.0 |
| | | elastic | | | | | | | | |
| | | modulus [GPa] | | | | | | | | |
| | Optical | Optical | 1.0 | 1.0 | 1.0 | 1.0 | 1.0 | 1.0 | 0.7 | 1.0 |
| | characteristics | density (OD) | | | | | | | | |
| | Organic EL | Evaluation of | Favor- | Favor- | Favor- | Favor- | Favor- | Favor- | Favor- | Favor- |
| | display | initial light | able | able | able | able | able | able | able | able |
| | characteristics | emission | | | | | | | | |
| | | Durability | Favor- | Favor- | Favor- | Favor- | Favor- | Favor- | Favor- | Favor- |
| | | evaluation | able | able | able | able | able | able | able | able |

TABLE 4

| | | | | | Example | | | Comparative Example | | | | |
|---|---|---|---|---|---|---|---|---|---|---|---|---|
| | | | | | 18 | 19 | 20 | 1 | 2 | 3 | 4 | 5 |
| Photosensitive resin composition | | | | | R | S | T | a | b | c | d | e |
| Used pigment dispersion | | | | | DSP- | DSP- | DSP- | DSP- | DSP- | DSP- | DSP- | — |
| | | | | | 1 | 1 | 1 | 4 | 5 | 1 | 1 | |
| Composition | (A) Component | | P1 (polyimide) | | 100 | 100 | 100 | | | 100 | 100 | 100 |
| (parts by mass) | | | P2 (polyimide | | | | | | | | | |
| | | | precursor) | | | | | | | | | |
| | | | P3 (PBO precursor) | | | | | | | | | |
| | | | P4 (acrylic resin) | | | | | 100 | | | | |
| | | | V259ME (cardo resin) | | | | | | 100 | | | |
| | (B) | (B-1) | DCP-M | Tg = 214 | 24 | 36 | 48 | 30 | 30 | | 60 | |
| | Component | | | [° C.] | | | | | | | | |
| | | (B-2 ) | DPCA-60 | Tg = 60 | | | | 30 | 30 | | | |
| | | | | [° C.] | | | | | | | | |
| | | | DPHA | Tg = 80 | 36 | 24 | 12 | | | 60 | | |
| | | | | [° C.] | | | | | | | | |

| Tg of (B) component as a polymer [° C.] | | | 124 | 150 | 180 | 123 | 123 | 80 | 214 | — |
|---|---|---|---|---|---|---|---|---|---|---|
| (C) Component | | NCI-831 | 15 | 15 | 15 | 15 | 15 | 15 | 15 | |
| (D) | Pigment | BLACK S0100CF | 60 | 60 | 60 | 60 | 60 | 60 | 60 | |
| Component | Dye | S.B.63 | | | | | | | | 30 |
| | | S.R.18 | | | | | | | | 20 |
| | | D.Y.201 | | | | | | | | 10 |
| (E) | (E-1) | MW-100-LM | 20 | 20 | 20 | 20 | 20 | 20 | 20 | 20 |
| Component | | | | | | | | | | |

| | | | | | | | | | |
|---|---|---|---|---|---|---|---|---|---|
| (F) Component | S-20000 | 20 | 20 | 20 | 20 | 20 | 20 | 20 | |
| Photo acid | | | | | | | | | 15 |
| generator | | | | | | | | | |
| Solvent | MBA | 1558 | 1558 | 1558 | 1558 | 1558 | 1558 | 1558 | |
| | GBL | | | | | | | | 1020 |

| | | | Example | | | Comparative Example | | | | |
|---|---|---|---|---|---|---|---|---|---|---|
| | | | 18 | 19 | 20 | 1 | 2 | 3 | 4 | 5 |
| Evaluation | Photosensitive | Sensitivity | 85 | 95 | 100 | 40 | 40 | 70 | 200 | 850 |
| results | characteristics | [mJ/cm²] | | | | | | | | |
| | Cured film | Taper angle | 35 | 40 | 48 | 30 | 33 | 28 | 72 | 25 |
| | characteristics | θ [°] | | | | | | | | |
| | | Step shape | A | A | A | D | D | D | A | A |
| | | Thickness of | 2.5 | 2.6 | 2.7 | Unmeasurable | Unmeasurable | Unmeasurable | 2.7 | 2.9 |
| | | thick film | | | | | | | | |
| | | part T_{FT} [μm] | | | | | | | | |
| | | Thickness of | 0.8 | 1.0 | 1.0 | | | | 1.2 | 1.0 |
| | | thin film | | | | | | | | |
| | | part T_{HT} [μm] | | | | | | | | |
| | | Film | 1.7 | 1.6 | 1.7 | | | | 1.5 | 1.9 |
| | | thickness | | | | | | | | |
| | | difference | | | | | | | | |
| | | ΔT_{FT-HT} [μm] | | | | | | | | |
| | | Dimension | <0.1 | <0.1 | <0.1 | 1.1 | 0.8 | 0.5 | <0.1 | <0.1 |
| | | change [μm] | | | | | | | | |
| | | Water | 0.8 | 0.7 | 0.6 | 0.8 | 0.7 | 1.3 | 0.6 | 1.1 |
| | | absorption [%] | | | | | | | | |
| | | Indentation | 8.0 | 7.8 | 7.9 | 6.8 | 6.9 | 7.5 | 7.6 | 7.7 |
| | | elastic | | | | | | | | |
| | | modulus [GPa] | | | | | | | | |
| | Optical | Optical | 1.0 | 1.0 | 1.0 | 1.0 | 1.0 | 1.0 | 1.0 | 1.0 |
| | characteristics | density (OD) | | | | | | | | |
| | Organic EL display | Evaluation of | Favor- | Favor- | Favor- | Favor- | Favor- | Favor- | No | Favor- |
| | characteristics | initial light | able | able | able | able | able | able | light | able |
| | | emission | | | | | | | emission | |
| | | Durability | Favor- | Favor- | Favor- | 50% | 30% | Favor- | Not | Favor- |
| | | evaluation | able | able | able | reduction | reduction | able | evaluated | able |
| | | | | | | in light | in light | | | |
| | | | | | | emitting | emitting | | | |
| | | | | | | area | area | | | |

According to Examples 1 to 20, a cured film with a favorable step shape was obtained in the case of curing at 250° C. Furthermore, according to Examples 1 to 16 and 18 to 20 where the glass transition temperature of the (B) radically polymerizable compound as a polymer was 110° C. or higher, a cured film with a favorable step shape was obtained even by the curing at 270° C., and according to Examples 1, 3 to 16, and 18 to 20 where the glass transition temperature of the (B) radically polymerizable compound as a polymer was 120° C. or higher, a cured film with a favorable step shape was obtained even in the case of curing at 300° C. On the other hand, according to Comparative Examples 1 and 2 where a resin other than a polyimide, a polyimide precursor, a polybenzoxazole precursor, and/or a copolymer thereof was used as the (A) alkali-soluble resin, and Comparative Example 3 containing only the (B-2) tetrafunctional or higher (meth)acrylic compound other than the (B-1) as the radically polymerizable compound, the step shape was lost due to pattern flow at the time of curing at 250° C. In addition, according to Comparative Example 4 containing, as the (B) radically polymerizable compound, only the (B-1) bifunctional or higher (meth)acrylic compound with a glass transition temperature of 150° C. or higher as a homopolymer, a cured film with a favorable step shape was obtained, no light was emitted in the evaluation of the initial light emission of the organic EL display characteristics. It is believed that because the taper angle was as high as 72°, a failure occurred such as disconnection of the second electrode.

According to Comparative Example 5 with the use of the positive photosensitive resin composition, a cured film with a favorable step shape was obtained under any curing condition of 250, 270, and 300° C., but the sensitivity was significantly degraded as compared with the Examples.

Furthermore, the cured films according to Examples 1 to 8 and 12 to 21 containing, as the (E) thermally crosslinking agent, the (E-1) compound having 6 or more and 20 or less methylol groups and/or alkoxymethyl groups in total was higher in indentation elastic modulus as compared with the cured films according to Examples 9 to 11 containing no (E-1) compound. This means that a cured film with higher hardness has been obtained, and it is believed that particle generation can be suppressed in bringing an evaporation mask into contact with the pixel defining layer.

Furthermore, Examples 1, 2 and 3 containing, as the (B-1) component, the (meth)acrylic compound having an alicyclic structure composed of only carbon atoms and hydrogen atoms were higher in sensitivity and lower in the water absorption of the obtained cured film, as compared with Example 4 containing the (meth)acrylic compound having an alicyclic structure including a hetero atom.

In addition, Examples 1 and 3 with the use of, as the (B-1) component, the radically polymerizable compound having a methacrylic group as a radically polymerizable group were higher in sensitivity and lower in the water absorption of the obtained cured film, as compared with Examples 2 and 4 with the use of the radically polymerizable compound having only an acrylic group as a radically polymerizable group.

In addition, Example 1 containing the lactone-modified (meth)acrylic compound as the (B-2) component was higher in sensitivity, as compared with Examples 5 and 6 containing the (meth)acrylic compound which was not modified with lactone.

Furthermore, as can be seen from the durability evaluation results of the organic EL display devices, Examples 1 to 20 exhibited favorable light-emitting characteristics even after the durability evaluation, whereas Comparative Examples 1 and 2 with the use of the resin other than a polyimide, a polyimide precursor, a polybenzoxazole precursor, and/or the a copolymer thereof as the (A) alkali-soluble resin as a resin have light-emitting areas reduced after the durability evaluation. It is believed that the organic light-emitting material was deteriorated by the gas component generated from the resin component which was low in heat resistance.

### DESCRIPTION OF REFERENCE SIGNS

1: Substrate
2: Cured film
3: Thick film part
4: Thin film part
5: Thin film part
6: Substrate
7: TFT
8: TFT insulation film
9: Wiring
10: Contact hole
11: Planarization layer
12: Electrode
13: Pixel defining layer
14: partial-transmitting portion
15: Light-blocking portion
16: Light-transmitting portion
17: Substrate
18: Insulation layer
19: Non-alkali glass substrate
20: First electrode
21: Auxiliary electrode
22: Pixel defining layer
23: Organic EL layer
24: Second electrode

1. A photosensitive resin composition comprising an (A) alkali-soluble resin, a (B) radically polymerizable compound, a (C) photo initiator, and a (D) colorant, wherein the (A) alkali-soluble resin contains a polyimide, a polyimide precursor, a polybenzoxazole precursor, and/or a copolymer thereof, and the (B) radically polymerizable compound contains a (B-1) bifunctional or higher (meth)acrylic compound that has a glass transition temperature of 150° C. or higher as a homopolymer, and a (B-2) tetrafunctional or higher (meth)acrylic compound other than the (B-1).

2. The photosensitive resin composition according to claim 1, wherein the (B-1) bifunctional or higher (meth)acrylic compound that has a glass transition temperature of 150° C. or higher as a homopolymer comprises an alicyclic structure.

3. The photosensitive resin composition according to claim 2, wherein the alicyclic structure comprises any of the group consisting of a tricyclodecanyl group, an adamantyl group, a hydroxyadamantyl group, a pentacyclopentadecanyl group, and an isocyanurate group.

4. The photosensitive resin composition according to claim 1, wherein the photosensitive resin composition is used for collectively forming a step shape of a pixel defining layer in an organic EL display device.

5. The photosensitive resin composition according to claim 1, wherein the (B-2) tetrafunctional or higher (meth)acrylic compound other than the (B-1) contains a (meth)acrylic compound containing a structure represented by the general formula (3). 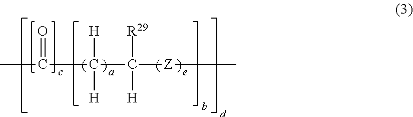
wherein in the general formula (3), R²⁹ represents hydrogen or a hydrocarbon group having 1 to 10 carbon atoms, Z represents either an oxygen atom or N—R³⁰, R³⁰ represents a hydrogen atom or a hydrocarbon group having 1 to 10 carbon atoms, a represents an integer of 1 to 10, b represents an integer of 1 to 10, c represents 0 or 1, d represents an integer of 1 to 4, and e represents 0 or 1, and in a case where c is 0, d is 1.

6. The photosensitive resin composition according to claim 5, wherein the (B-2) tetrafunctional or higher (meth)acrylic compound other than the (B-1) contains a (meth)acrylic compound having a lactone-modified chain and/or a lactam-modified chain.

7. The photosensitive resin composition according to claim 1, wherein the (B-1) bifunctional or higher (meth)acrylic compound that has a glass transition temperature of 150° C. or higher as a homopolymer comprises a methacrylic group.

8. The photosensitive resin composition according to claim 1 wherein with respect to 100 parts by mass of the (B) radically polymerizable compound, a content of the (B-1) bifunctional or higher (meth)acrylic compound that has a glass transition temperature of 150° C. or higher as a homopolymer is 20 to 80 parts by mass, and a content of the (B-2) tetrafunctional or higher (meth)acrylic compound other than the (B-1) is 20 to 80 parts by mass.

9. The photosensitive resin composition according to claim 1, further comprising a (E) thermally crosslinking agent.

10. The photosensitive resin composition according to claim 9, wherein the (E) thermally crosslinking agent contains a (E-1) compound having 6 or more and 20 or less methylol groups and/or alkoxymethyl groups in total.

11. The photosensitive resin composition according to claim 1, wherein the colorant (D) contains a black pigment and/or a perylene-based black pigment that has a benzofuranone structure.

12. A cured film comprising a cured product of the photosensitive resin composition according to claim 1.

13. The cured film according to claim 12, wherein the cured film has a step shape.

14. The cured film according to claim 12, wherein the cured film has an indentation elastic modulus in a range of 7.0 GPa or more and 12.0 GPa or less.

15. The cured film according to claim 13, wherein in a case where a film thickness of a thick film part of the cured film with the step shape is denoted by (T_{FT}), a film thickness of a thin film part thereof is denoted by (T_{HT}) μm, and a film thickness difference between the film thickness (T_{FT}) of the thick film part and the film thickness (T_{HT}) of the thin film part is denoted by (ΔT_{FF-HT}) μm, the thickness (T_{FT}) of the thick film part, the thickness (T_{HT}) of the thin film part, and the film thickness difference (ΔT_{FT-HT}) between the film thickness of the thick film part and the film thickness of the thin film part satisfy relations represented by the formulas (α) to (γ):
1.0≤(T_{FT})≤5.0 (α)
0.2≤(T_{HT})≤4.0 (β)
0.5≤(ΔT_{FT-HT})≤4.0 (γ)

16. An element comprising the cured film according to claim 12.

17. An organic EL display device comprising the cured film according to claim 12.

18. A method for producing a cured film, the method comprising:
(1) a step of applying the photosensitive resin composition according to claim 1 to a substrate to form a photosensitive resin film;
(2) a step of drying the photosensitive resin film;
(3) a step of exposing the dried photosensitive resin film through a photomask;
(4) a step of developing the exposed photosensitive resin film; and
(5) a step of applying a heat treatment to the developed photosensitive resin film.

19. The method for producing a cured film according to claim 18, wherein the photomask is a photomask that has a pattern including a light-transmitting portion and a light-blocking portion, the photomask being a half-tone photomask including, between the light-transmitting portion and the light-blocking portion, a partial-transmitting portion that is lower in transmittance than a value of the light-transmitting portion and higher in transmittance than a value of the light-blocking portion.

20. A method for producing an organic EL display device, the method comprising a step of forming a cured film by the method according to claim 18.
